(19) United States
(12) Patent Application Publication
(10) Pub. No.: US 2023/0103371 A1
(43) Pub. Date: Apr. 6, 2023

(54) PHOTORESIST UNDERLAYER COMPOSITION

(71) Applicant: Rohm and Haas Electronic Materials LLC, Marlborough, MA (US)

(72) Inventors: Iou-Sheng Ke, Andover, MA (US); Anton Chavez, West Newton, MA (US); Shintaro Yamada, Shrewsbury, MA (US)

(21) Appl. No.: 17/490,816

(22) Filed: Sep. 30, 2021

(51) Int. Cl. G03F 7/11; C09D 133/14; C09D 125/18

(52) U.S. Cl. CPC G03F 7/11; C09D 133/14; C09D 125/18

(57) ABSTRACT

A photoresist underlayer composition, comprising a first material comprising two or more hydroxy groups; a second material comprising two or more glycidyl groups; an additive, wherein the additive comprises a compound of Formula (5), a compound of Formula (6), or a combination thereof; and a solvent, wherein the structures of Formula (5) and (6) are as disclosed herein.

### FIELD

The present invention relates generally to field of manufacturing electronic devices, and more specifically to the field of materials for use in semiconductor manufacture.

### BACKGROUND

Photoresist underlayer compositions are used in the semiconductor industry as etch masks for lithography in advanced technology nodes for integrated circuit manufacturing. These compositions are often used in tri-layer and quad-layer photoresist integration schemes, where an organic or silicon containing anti-reflective coating and a patternable photoresist film layers are disposed on the bottom layer having a high carbon content.

Spin-on Carbon (SOC) compositions are used as resist underlayer films in the semiconductor industry as etch masks for lithography in advanced technology nodes for integrated circuit manufacturing. These compositions are often used in tri-layer and quad-layer photoresist integration schemes, where an organic or silicon containing anti-reflective coating and a patternable photoresist film layers are disposed on the bottom layer having a high carbon content SOC material.

An ideal SOC material should possess certain specific characteristics: it should be capable of being cast onto a substrate by a spin-coating process, should be thermally set upon heating with low out-gassing and sublimation, should be soluble in common solvents for good spin bowl compatibility, should have appropriate n/k to work in conjunction with the anti-reflective coating layer to impart low reflectivity necessary for photoresist imaging, and should have high thermal stability to avoid being damaged during subsequent processing steps. In addition, it is desirable for the underlayer film to be sufficiently adhered to the substrate to avoid delamination when submerged, for example, during a standard cleaning process known as SC-1 using a hydrogen peroxide/ammonium hydroxide bath.

Accordingly, there remains a need for new photoresist underlayer materials that can improve adhesion to underlying substrates and that have good strip resistance and resistance to SC-1 cleaning conditions.

### SUMMARY

Provided is a photoresist underlayer composition including a first material comprising two or more hydroxy groups; a second material comprising two or more glycidyl groups; an additive, wherein the additive comprises a compound of Formula (5), a compound of Formula (6), or a combination thereof; and a solvent,

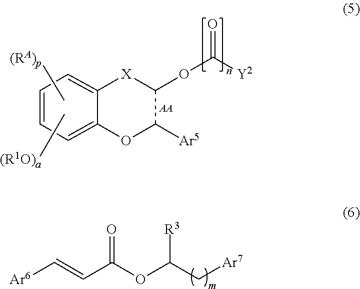

wherein, in Formulae (5) and (6), AA represents a single bond or a double bond; X is a single bond, —C(O)—, unsubstituted C₁ alkylene, or hydroxy-substituted C₁ alkylene; Ar⁵, Ar⁶, and Ar⁷ are each independently C₆₋₆₀ aryl or C₁₋₆₀ heteroaryl; wherein Ar⁵, Ar⁶, and Ar⁷ are each independently substituted with at least two groups of formula —OR²; optionally, wherein Ar⁵, Ar⁶, and Ar⁷ are each independently further substituted; R¹ and R² are each independently hydrogen, substituted or unsubstituted C₁₋₃₀ alkyl, substituted or unsubstituted C₃₋₃₀ cycloalkyl, —C(O)OR^{5a}, or glycidyl; each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; each R^{5a} is independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl; R³ is hydrogen, substituted or unsubstituted C₁₋₃₀ alkyl, substituted or unsubstituted C₃₋₃₀ cycloalkyl, substituted or unsubstituted C₁₋₃₀ heterocycloalkyl, a carboxylic acid group or a derivative thereof, or —C(O)OR^{5b}; R^{5b} is substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl; a is an integer from 2 to 4; m is an integer from 1 to 6; n is 0 or 1; p is an integer from 0 to 2; and Y² is hydrogen, substituted or unsubstituted C₆₋₆₀ aryl, or substituted or unsubstituted C₁₋₆₀ heteroaryl

Also provided is a coated substrate including a layer of the above-described photoresist underlayer composition disposed on a substrate; and a photoresist layer disposed on the layer of the photoresist underlayer composition.

Another aspect provides a method of forming a pattern including applying a layer of the above-described photoresist underlayer composition on a substrate to form a coated underlayer; forming a photoresist layer over the coated underlayer; patterning the photoresist layer; and transferring a pattern from the patterned photoresist layer to the coated underlayer and to a layer below the coated underlayer.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the figures, to explain aspects of the present description. As used herein, the term “and/or” includes all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, the term “hydrocarbon group” refers to an organic compound having at least one carbon atom and at least one hydrogen atom, optionally substituted with one or more substituents where indicated; “alkyl group” refers to a straight or branched chain saturated hydrocarbon having the specified number of carbon atoms and having a valence of one; “alkylene group” refers to an alkyl group having a valence of two; “hydroxyalkyl group” refers to an alkyl group substituted with at least one hydroxyl group (—OH); “alkoxy group” refers to “alkyl-O—”; “carboxylic acid group” refers to a group having the formula “—C(O)—OH”; “cycloalkyl group” refers to a monovalent group having one or more saturated rings in which all ring members are carbon; “cycloalkylene group” refers to a cycloalkyl group having a valence of two; “alkenyl group” refers to a straight or branched chain, monovalent hydrocarbon group having at least one carbon-carbon double bond; “alkenoxy group” refers to “alkenyl-O—”; “alkenylene group” refers to an alkenyl group having a valence of at least two; “cycloalkenyl group” refers to a cycloalkyl group having at least one carbon-carbon double bond; “alkynyl group” refers to a monovalent hydrocarbon group having at least one carbon-carbon triple bond; the term “aromatic group” denotes the conventional idea of aromaticity as defined in the literature, in particular in IUPAC 19, and refers to a monocyclic or polycyclic aromatic ring system that includes carbon atoms in the ring or rings, and optionally may include one or more heteroatoms independently selected from N, O, and S instead of a carbon atom or carbon atoms in the ring or rings; “aryl group” refers to a monovalent, monocyclic or polycyclic aromatic group containing only carbon atoms in the aromatic ring or rings, and may include a group with an aromatic ring fused to at least one cycloalkyl or heterocycloalkyl ring; “arylene group” refers to an aryl group having a valence of at least two; “alkylaryl group” refers to an aryl group that has been substituted with an alkyl group; “arylalkyl group” refers to an alkyl group that has been substituted with an aryl group; “aryloxy group” refers to “aryl-O—”; and “arylthio group” refers to “aryl-S—”.

The prefix “hetero” means that the compound or group includes at least one member that is a heteroatom (e.g., 1, 2, 3, or 4 or more heteroatom(s)) instead of a carbon atom, wherein the heteroatom(s) is each independently selected from N, O, S, Si, or P; “heteroatom-containing group” refers to a substituent group that includes at least one heteroatom; “heteroalkyl group” refers to an alkyl group having 1-4 heteroatoms instead of carbon atoms; “heterocycloalkyl group” refers to a cycloalkyl group with one or more N, O or S atoms instead of carbon atoms; “heterocycloalkylene group” refers to a heterocycloalkyl group having a valence of at least two; “heteroaryl group” refers to an aryl group having 1 to 3 separate or fused rings with one or more N, O or S atoms as ring members instead of carbon atoms; and “heteroarylene group” refers to a heteroaryl group having a valence of at least two.

The term “halogen” means a monovalent substituent that is fluorine (fluoro), chlorine (chloro), bromine (bromo), or iodine (iodo). The prefix “halo” means a group including one more of a fluoro, chloro, bromo, or iodo substituent instead of a hydrogen atom. A combination of halo groups (e.g., bromo and fluoro), or only fluoro groups may be present.

The symbol “*” represents a bonding site (i.e., point of attachment) of a repeating unit.

“Substituted” means that at least one hydrogen atom on the group is replaced with another group, provided that the designated atom's normal valence is not exceeded. When the substituent is oxo (i.e., O), then two hydrogens on the carbon atom are replaced. Combinations of substituents or variables are permissible. Exemplary groups that may be present on a “substituted” position include, but are not limited to, nitro (—NO₂), cyano (—CN), hydroxyl (—OH), oxo (O), amino (—NH2), mono- or di-(C₁₋₆)alkylamino, alkanoyl (such as a C₂₋₆ alkanoyl group such as acyl), formyl (—C(O)H), carboxylic acid or an alkali metal or ammonium salt thereof, C₂₋₆ alkyl ester (—C(O)O-alkyl or —OC(O)-alkyl), C₇₋₁₃ aryl ester (—C(O)O-aryl or —OC(O)-aryl), amido (—C(O)NR₂ wherein R is hydrogen or C₁₋₆ alkyl), carboxamido (—CH₂C(O)NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₄₋₁₂ heterocycloalkyl, C₃₋₁₂ heteroaryl, C₁₋₆ alkyl sulfonyl (—S(O)₂-alkyl), C₆₋₁₂ arylsulfonyl (—S(O)₂-aryl), or tosyl (CH₃C₆H₄SO₂—). When a group is substituted, the indicated number of carbon atoms is the total number of carbon atoms in the group, excluding those of any substituents. For example, the group —CH₂CH₂CN is a C₂ alkyl group substituted with a cyano group.

As used herein, the terms “polymer” and “polymeric” refer to a polymeric material that includes one or more repeating units, where the repeating units may be the same or different from each other. Thus, the disclosed polymers and polymeric materials of the invention can be referred to herein as a “polymer” or a “copolymer.” It is to be further understand that the terms “polymer” and “polymeric” further include oligomers. As used herein, each of the one or more different repeating units are present in the polymeric material at least two times. In other words, a polymeric material including one repeating unit includes a first repeating unit that is present in an amount of two or more, and, for example, a polymeric material including two repeating units includes a first repeating unit that is present in an amount of two or more, and a second repeating unit that is present in an amount of two or more.

As used herein, when a definition is not otherwise provided, a “divalent linking group” refers to a divalent group including one or more of —O—, —S—, —Te—, —Se—, —C(O)—, —N(R^{a})—, —S(O)—, —S(O)₂—, —C(S)—, —C(Te)—, —C(Se)—, substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted C₇₋₃₀ arylalkylene, substituted or unsubstituted C₁₋₃₀ heteroarylene, substituted or unsubstituted C₃₋₃₀ heteroarylalkylene, or a combination thereof, wherein R^{a} is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₄₋₃₀ heteroaryl. More typically, the divalent linking group includes one or more of —O—, —S—, —C(O)—, —5(O)—, —S(O)2-, substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted C₇₋₃₀ arylalkylene, substituted or unsubstituted C₁₋₃₀ heteroarylene, substituted or unsubstituted C₃₋₃₀ heteroarylalkylene, or a combination thereof, wherein R′ is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₄₋₃₀ heteroaryl.

Organic underlayer films may be used to protect underlying substrates during various pattern transfer and etch processes. Often these films are cast and cured directly upon an inorganic substrate (i.e., TiN). In these cases, it is desirable that the underlayer film has sufficient adhesion to the substrate during all subsequent processing steps to protect the substrate from otherwise damaging conditions. One commonly used processing step is the wet etch process known as SC-1, which involves submerging the substrate into a hydrogen peroxide/ammonium hydroxide bath. An underlayer film that is not sufficiently adhered to the substrate may delaminate while it is submerged, resulting in exposure of and damage to the underlying inorganic substrate.

The present invention provides an additive for a photoresist underlayer formulation that may be applied to form a coating layer over a substrate. The present inventors have discovered that EUV underlayer and/or BARC formulations including an additive having multiple phenolic hydroxy groups that are distributed on distant aromatic groups can be used to increase phenolic density. The inventive additive can be used in photoresist underlayer compositions to achieve improved adhesion to substrates and to enhance the mechanical properties of the resulting films. The multiple phenolic hydroxy groups of the inventive additive enhance the adhesion of the underlayer film to a substrate, particularly when the film and substrate are submerged into a hydrogen peroxide/ammonium hydroxide (SC-1) bath.

According to an aspect of the invention, a photoresist underlayer composition is provided that includes a first material comprising two or more hydroxy groups; a second material comprising two or more glycidyl groups; an additive comprising a compound of Formula (5) as described below, a compound of Formula (6) as described below, or a combination thereof; and a solvent.

The first material comprises two or more hydroxy groups and may be polymeric or non-polymeric. In some aspects, the first material may be a polymer comprising two or more hydroxy groups, for example a polymer having a repeating unit that comprises one or more hydroxy groups, or a repeating unit that comprises 1 to 4 hydroxy groups, preferably a repeating unit that comprises 1 to 3 hydroxy groups, and more typically a repeating unit that comprises 1 or 2 hydroxy groups. In some aspects, the polymer may have a first repeating unit that comprises one or more hydroxy groups and a second repeating unit that comprises one or more hydroxy groups, wherein the first repeating unit and the second repeating unit are different.

For example, a first material that is a polymer comprising two or more hydroxy groups may be derived from a monomer comprising a polymerizable group and one or more hydroxy groups. In an embodiment, the polymer comprising two or more hydroxy groups may include a repeating unit derived from a monomer of Formula (1):

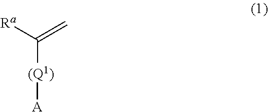

wherein R^{a} may be hydrogen, fluorine, cyano, substituted or unsubstituted C₁₋₁₀ alkyl, or substituted or unsubstituted C₁₋₁₀ fluoroalkyl. Preferably, R^{a} is hydrogen, fluorine, or substituted or unsubstituted C₁₋₅ alkyl, typically methyl.

Q¹ is a divalent linking group, and is typically selected from one or more of substituted or unsubstituted C₁₋₃₀ alkylene, substituted or unsubstituted C₃₋₃₀ cycloalkylene, substituted or unsubstituted C₁₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, substituted or unsubstituted divalent C₃₋₃₀ heteroarylalkyl, —C(O)—O—, or —C(O)—NR^{1a}, wherein R^{1a} is hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl.

A is a C₆₋₃₀ aryl group substituted with one or more hydroxy groups or a C₄₋₆₀ heteroaryl group substituted with one or more hydroxy groups. Optionally, each of the hydroxy-substituted C₆₋₃₀ aryl group and the hydroxy-substituted C₄₋₆₀ heteroaryl group may be further substituted with one or more of substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, C₃₋₃₀ alkylheteroaryl, —OR^{1a}, or —NR^{1b}R^{1c}, wherein R^{1a} to R^{1c} are each independently substituted or unsubstituted C₁₋₃₀ alkyl, substituted or unsubstituted C₃₋₃₀ cycloalkyl, substituted or unsubstituted C₁₋₃₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₄₋₃₀ heteroaryl, substituted or unsubstituted C₅₋₃₀ heteroarylalkyl, or substituted or unsubstituted C₅₋₃₀ alkylheteroaryl.

Non-limiting examples of monomers of Formula (1) include:

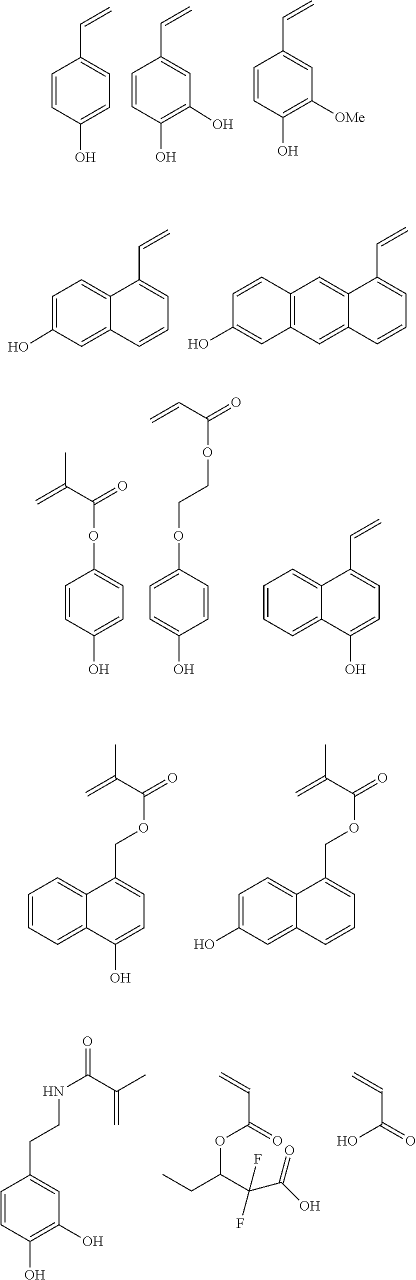

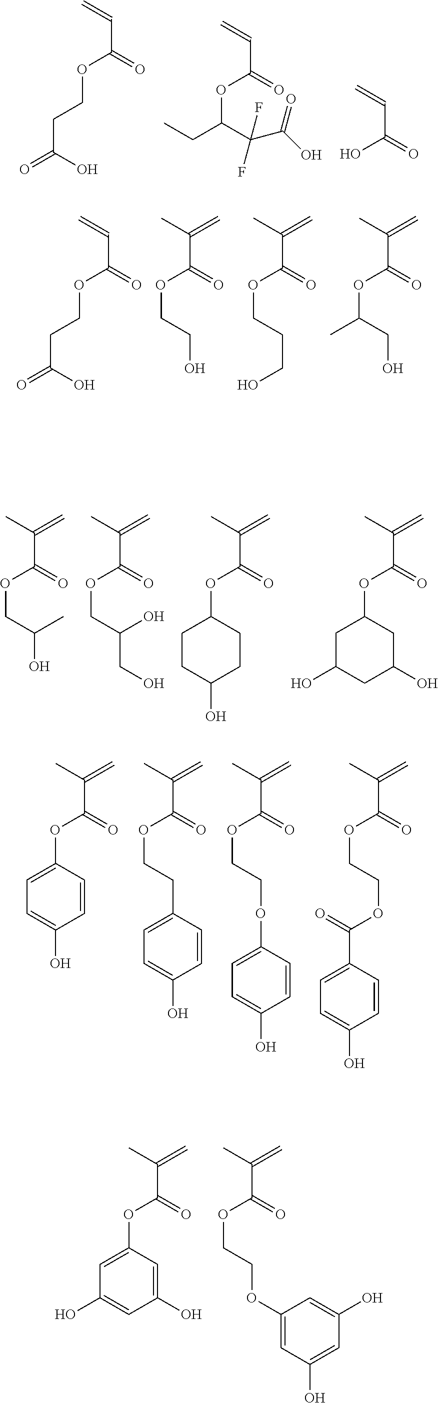

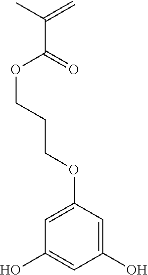 [SMILES: C=C(C)C(=O)OCCCOc1cc(O)cc(O)c1]

Another exemplary monomer for forming a repeating unit of the polymer comprising the two or more hydroxy groups includes an N-hydroxyaryl maleimide monomer of Formula (2):

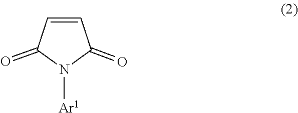

wherein Ar¹ is a hydroxy-substituted C₆₋₆₀ aryl group, a hydroxy-substituted C₄₋₆₀ heteroaryl group, or a combination thereof, optionally further substituted with one or more of substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₂₋₃₀ heteroaryl, substituted or unsubstituted C₃₋₃₀ heteroarylalkyl, C₃₋₃₀ alkylheteroaryl, —OR^{2a} or —NR^{2b}R^{2c}, wherein R^{2a} to R^{2c} are each independently substituted or unsubstituted C₁₋₃₀ alkyl, substituted or unsubstituted C₃₋₃₀ cycloalkyl, substituted or unsubstituted C₁₋₃₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₄₋₃₀ heteroaryl, substituted or unsubstituted C₅₋₃₀ heteroarylalkyl, or substituted or unsubstituted C₅₋₃₀ alkylheteroaryl. It may be desired for Ar¹ to include a single hydroxyl group or a plurality of hydroxyl groups.

Non-limiting examples of N-hydroxyaryl maleimide monomers of Formula (2) include the following:

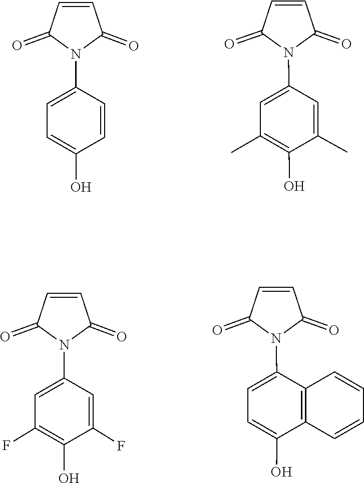 [SMILES: O=C1C=CC(=O)N1c1ccc(O)cc1 ; Cc1cc(N2C(=O)C=CC2=O)cc(C)c1O ; O=C1C=CC(=O)N1c1cc(F)c(O)c(F)c1 ; O=C1C=CC(=O)N1c1ccc(O)c2ccccc12]

In some aspects, the polymer may include a repeating unit comprising an aromatic group or a heteroaromatic group that is incorporated into the polymer backbone. For example, the polymer may include a repeating unit of Formulae (3a), (3b), or a combination thereof:

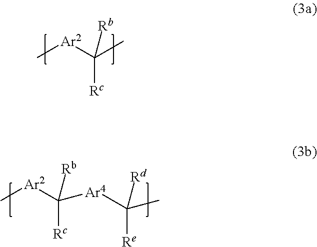

In Formulae (3a) and (3b), Ar² and Ar³ are each independently a substituted or unsubstituted C₅₋₆₀ aromatic group that is substituted with at least one hydroxy group or a substituted or unsubstituted C₁₋₆₀ heteroaromatic group that is substituted with at least one hydroxy group. For example, the aromatic or heteroaromatic group typically includes 1 to 3 hydroxy groups or 1 or 2 hydroxy groups. the term “substituted with at least one hydroxy group” in the context of the unsubstituted C₅₋₆₀ aromatic group and the unsubstituted C₁₋₆₀ heteroaromatic group means the corresponding aromatic or heteroaromatic group is substituted with the at least one hydroxy group and is not further substituted with additional groups or substituents that are not hydroxy.

The C₅₋₆₀ aromatic group and the C₁₋₆₀ heteroaromatic group may optionally further include one or more heteroatoms chosen from N, O, or S. It is to be understand that the one or more optional heteroatoms of the C₅₋₆₀ aromatic group and the C₁₋₆₀ heteroaromatic group are present as one or more heteroatoms of a heteroatom-containing substituent group. It is to be understand that the heteroatom or heteroatoms of the C₁₋₆₀ heteroaromatic group in Formulae (3a) and (3b) are present as aromatic ring members instead of carbon atoms (e.g., Ar² and/or Ar³ may be a heteroarylene group).

The C₅₋₆₀ aromatic group and the C₁₋₆₀ heteroaromatic group may be monocyclic or polycyclic. When the group is polycyclic, the ring or ring groups can be fused (such as naphthyl or the like), directly linked (such as biaryls, biphenyl, or the like), bridged by a heteroatom (such as triphenylamino or diphenylene ether), or a combination thereof. In an embodiment, the polycyclic aromatic group may include a combination of fused and directly linked rings (such as binaphthyl or the like).

In addition to the at least one hydroxy group, and as described hereinabove, the substituted C₅₋₆₀ aromatic group and the substituted C₁₋₆₀ heteroaromatic group of Formulae (3a) and (3b) are further substituted. Exemplary substituents include, but are not limited to, substituted or unsubstituted C₁₋₃₀ alkyl, substituted or unsubstituted C₁₋₃₀ haloalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ heteroarylalkyl, halogen, —OR³¹, —SR³², or —NR³³R³⁴, wherein R³¹ is substituted or unsubstituted C₁₋₃₀ alkyl, substituted or unsubstituted C₃₋₃₀ cycloalkyl, substituted or unsubstituted C₂₋₃₀ heterocycloalkyl, substituted or unsubstituted C₆₋₃₀ aryl, substituted or unsubstituted C₇₋₃₀ arylalkyl, substituted or unsubstituted C₃₋₃₀ heteroaryl, or substituted or unsubstituted C₄₋₃₀ heteroarylalkyl; and R³² to R³⁴ are each independently hydrogen, substituted or unsubstituted C₁₋₃₀ alkyl, substituted or unsubstituted C₃₋₃₀ cycloalkyl, substituted or unsubstituted C₂₋₃₀ heterocycloalkyl, substituted or unsubstituted C₆₋₃₀ aryl, substituted or unsubstituted C₇₋₃₀ arylalkyl, substituted or unsubstituted C₃₋₃₀ heteroaryl, or substituted or unsubstituted C₄₋₃₀ heteroarylalkyl.

In Formula (3b), Ar⁴ is a substituted or unsubstituted C₅₋₆₀ aromatic group or a substituted or unsubstituted C₁₋₆₀ heteroaromatic group. The C₅₋₆₀ aromatic group and the C₁₋₆₀ heteroaromatic group may optionally further include one or more heteroatoms chosen from N, O, or S. It is to be understand that the one or more optional heteroatoms of the C₅₋₆₀ aromatic group and the C₁₋₆₀ heteroaromatic group are present as one or more heteroatoms of a heteroatom-containing substituent group. It is to be understand that the heteroatom or heteroatoms of the C₁₋₆₀ heteroaromatic group in Formula (3b) are present as aromatic ring members instead of carbon atoms (e.g., Ar⁴ may be a heteroarylene group).

In Formulae (3a) and (3b), R^{b}, R^{c}, R^{d}, and R^{e} are each independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, or substituted or unsubstituted C₄₋₃₀ heteroarylalkyl. Preferably, R^{b}, R^{c}, R^{d}, and R^{e} are each independently hydrogen or substituted or unsubstituted C₁₋₁₀ alkyl, with hydrogen being typical.

Exemplary repeating units of Formula (3a) may include one or more of:

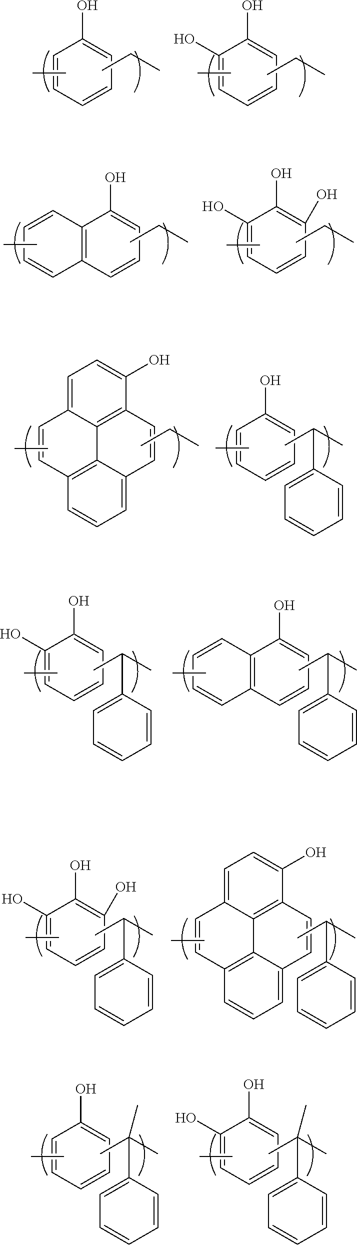

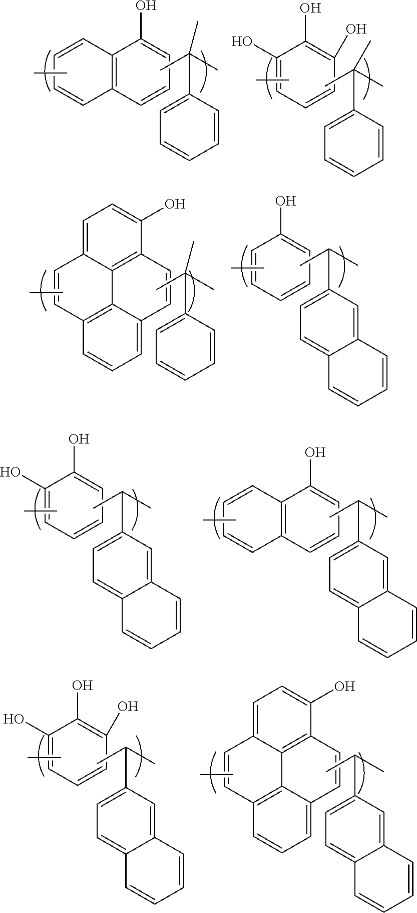

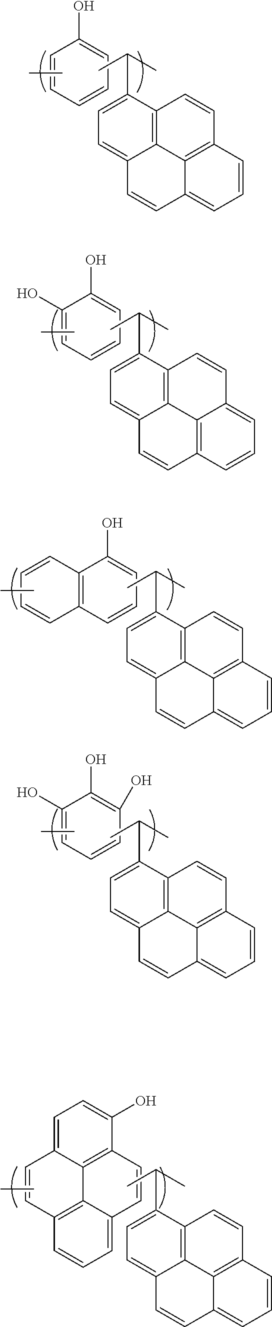

Exemplary repeating units of Formula (3b) may include one or more of:

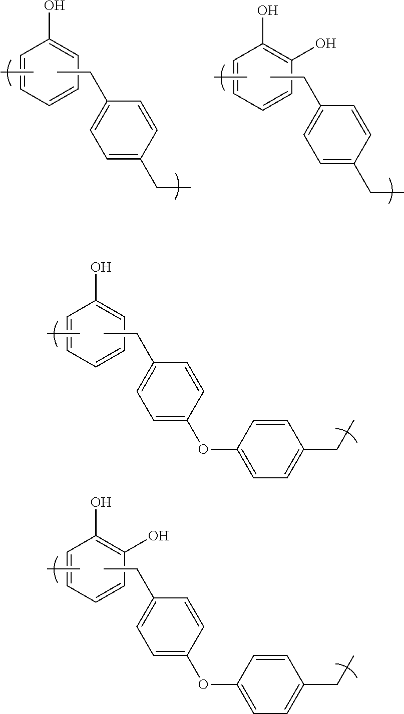

The polymer comprising two or more hydroxy groups may include a repeating unit comprising one or more hydroxy groups in an amount from 2 to 100 mol %, typically 10 to 100 mol %, more typically 50 to 100 mol % based on total repeating units in the polymer.

In other aspects, the first material comprising two or more hydroxy groups may be non-polymeric. Exemplary non-polymeric materials comprising two or more hydroxy groups include, but are not limited to, tris(4-hydroxyphenyl)methane, 2,6-bis(4-hydroxy-3,5-dimethylbenzyl)-4-methylphenol, 1,1,2,2-tetrakis(4-hydroxyphenyl)ethane, α, α, α′, α′-tetrakis(4-hydroxyphenyl)-p-xylene, 2,2-bis[4,4-bis(4-hydroxybenzyl)-cyclohexyl]propane, or a combination thereof.

The first material of the coating composition may generally be present in an amount from 5 to 95 weight percent (wt %) of the total solids of the coating composition, more typically in an amount from 25 to 75 wt % of the total solids of the coating composition. As used herein, the “total solids” of the coating composition refers to all materials and components of the coating composition except for the solvent carrier.

The coating composition further includes a second material that comprises two or more glycidyl groups. The second material may be a non-polymeric material or a polymeric material. In an embodiment, the second material comprising the two or more glycidyl groups may be a non-polymeric compound comprising two or more glycidyl groups or a polymer comprising two or more glycidyl groups.

Particularly suitable second materials may be polymers that include a repeating unit derived from a monomer of Formula (4):

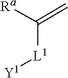

wherein R^{a} is hydrogen, fluorine, cyano, substituted or unsubstituted C₁₋₁₀ alkyl, or substituted or unsubstituted C₁₋₁₀ fluoroalkyl. Preferably, R^{a} is hydrogen, fluorine, or substituted or unsubstituted C₁₋₅ alkyl, typically methyl.

In Formula (4), L¹ is a divalent linking group, and, typically may be selected from substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, substituted or unsubstituted divalent C₂₋₃₀ heteroarylalkyl, —O—, —C(O)—, —N(R^{4a})—, —S—, or —S(O)₂—. R^{4a} may be hydrogen, substituted or unsubstituted C₁₋₂₀ alkyl, substituted or unsubstituted C₃₋₂₀ cycloalkyl, substituted or unsubstituted C₂₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, or substituted or unsubstituted C₂₋₃₀ heteroarylalkyl. Y¹ may be selected from substituted or unsubstituted C₁₋₃₀ alkyl, or substituted or unsubstituted C₆₋₃₀ aryl, wherein Y¹ comprises at least one epoxy group. In some embodiments, L and Y optionally may be taken together to form a carbon alicyclic ring that comprises a pendant or fused epoxy group.

Exemplary monomers of Formula (4) include:

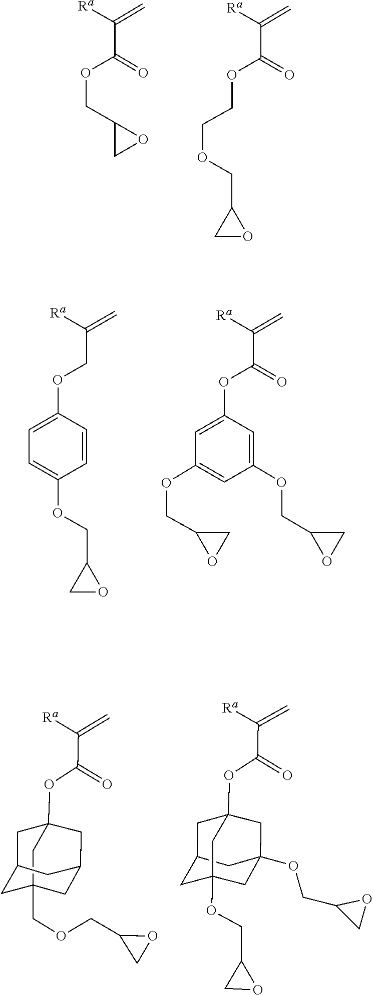

wherein R^{a} is the same as defined in Formula (4).

Exemplary second materials that are polymeric may have one or more repeating units selected from the formulae:

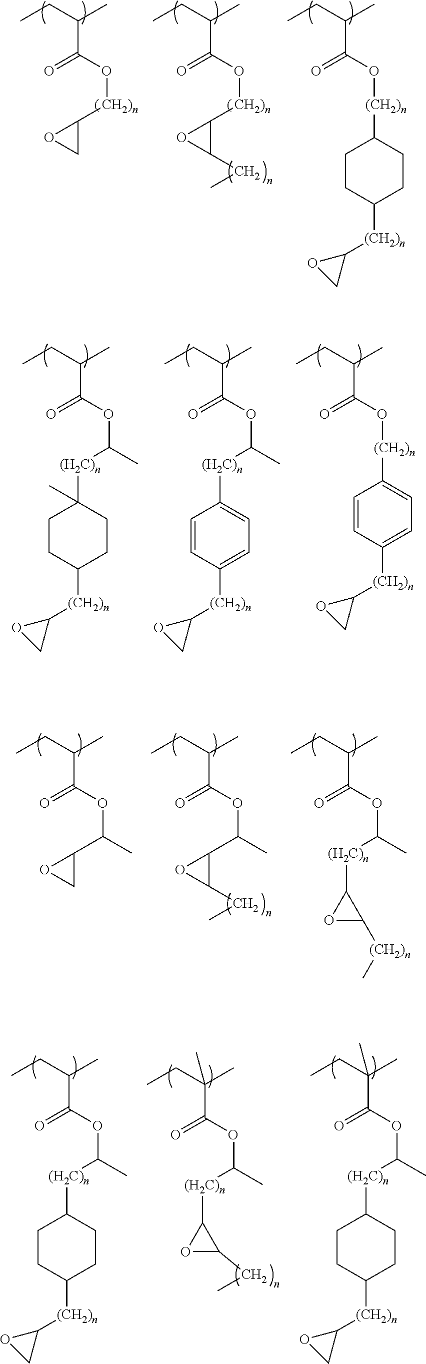

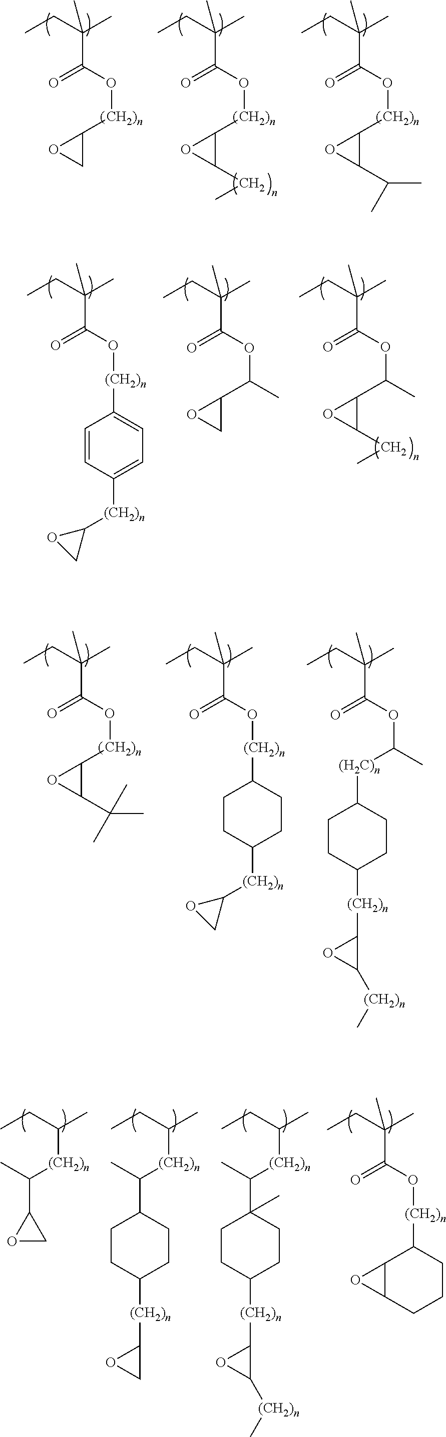

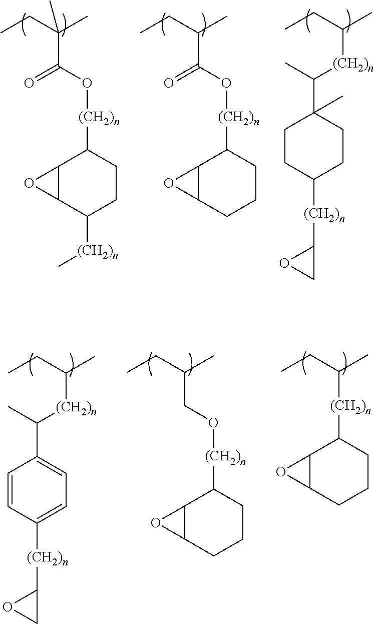

wherein each n is interdependently an integer from 1 to 6.

In some aspects, the second material comprising the two or more glycidyl groups may be a non-polymeric material or compound. Exemplary non-polymeric second materials include glycidyl-containing compounds, which may be selected from 1,1,2,2-tetra(p-hydroxyphenyl)ethane tetraglycidyl ether, glycerol triglycidyl ether, ortho-sec-butylphenyl glycidyl ether, 1,6-bis(2,3-epoxypropoxy)naphthalene, diglycerol polyglycidyl ether, polyethylene glycol glycidyl ether, triglycidyl isocyanurate, 4,4′-methylenebis(N,N-diglycidylaniline), or a combination thereof.

The second material of the photoresist underlayer composition generally may be present in an amount from 5 to 99 wt % of total solids of the photoresist underlayer composition, more typically in an amount from 25 to 75 wt % of total solids of the photoresist underlayer composition.

Preferably, when the first material and/or second material is polymeric, the respective polymer may have a weight average molecular weight (M_{w}) of 1,000 to 10,000,000 grams per mole (g/mol), more typically 2,000 to 10,000 g/mol, and a number average molecular weight (Mₙ) of 500 to 1,000,000 g/mol. Molecular weights (either M_{w} or Mₙ) are suitably determined by gel permeation chromatography (GPC) using polystyrene standards.

The photoresist underlayer composition includes an additive that comprises a compound of Formula (5), a compound of Formula (6), or a combination thereof:

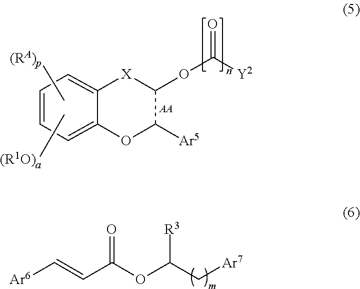

wherein AA is a single bond or a double bond.

In Formula (5), X is a single bond, —C(O)—, unsubstituted C₁ alkylene, or hydroxy-substituted C₁ alkylene. It is to be understood that the “hydroxy-substituted C₁ alkylene” is not further substituted with a group other than hydroxy. For example, X may be —C(O)— or unsubstituted C₁ alkylene.

In Formulae (5) and (6), Ar⁵, Ar⁶, and Ar⁷ are each independently C₆₋₆₀ aryl or C₁₋₆₀ heteroaryl, wherein each of Ar⁵, Ar⁶, and Ar⁷ is independently substituted with at least two groups of formula —OR². In some aspects, each of Ar⁵, Ar⁶, and Ar⁷ independently may be further substituted with a group different than formula —OR².

In Formulae (5) and (6), R¹ and R² are each independently hydrogen, substituted or unsubstituted C₁₋₃₀ alkyl, substituted or unsubstituted C₃₋₃₀ cycloalkyl, —C(O)OR^{5a}, or glycidyl, wherein R^{5a} is hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl. Typically, R¹ and R² may be hydrogen. a is an integer from 2 to 4, typically 2 or 3. m is an integer from 1 to 6, typically from 1 to 3. n is 0 or 1.

In Formula (5), each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl. Typically, each R^{A} is unsubstituted C₁₋₆ alkyl. p is an integer from 0 to 2, typically 0 or 1.

In Formula (6), R³ is hydrogen, substituted or unsubstituted C₁₋₃₀ alkyl, substituted or unsubstituted C₃₋₃₀ cycloalkyl, substituted or unsubstituted C₁₋₃₀ heterocycloalkyl, a carboxylic acid group or a derivative thereof, or —C(O)OR^{5b}, wherein R^{5b} is substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl. Typically, R³ may be hydrogen, a carboxylic acid group or a derivative thereof, or —C(O)OR^{5b}, preferably a carboxylic acid group or a derivative thereof. As used herein, “carboxylic acid or derivative thereof” refers to a carboxylic acid (—COOH) or a carboxylic acid derivative of the formula —COO⁻M⁺, wherein M⁺ is a cationic organic or inorganic group, for example an alkylammonium cation.

In Formula (5), Y² is hydrogen, substituted or unsubstituted C₆₋₆₀ aryl, or substituted or unsubstituted C₁₋₆₀ heteroaryl. It is to be understood that when n is 0, the oxygen atom is directly bonded to group Y² to form a partial structure represented by —O—Y². In some aspects, n is 0 and Y² is hydrogen. In other aspects, n is 1 and Y² is substituted or unsubstituted C₆₋₆₀ aryl, preferably a C₆₋₆₀ aryl substituted with two or more hydroxy groups, for example 2, 3, or 4 hydroxy groups, typically from 2 to 3 hydroxy groups, wherein the C₆₋₆₀ aryl group optionally may be further substituted with one or more substituent groups that are not hydroxy.

In some aspects, the additive of Formula (5) may be a compound that is represented by Formula (5a):

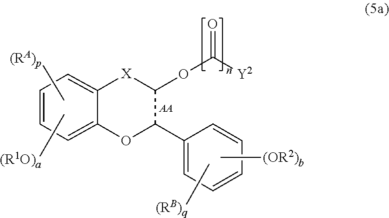

In Formula (5a), AA, X, R¹, R², Y², a, and n are the same as defined for Formula (5); each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; each R^{B} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; b is an integer from 2 to 5, preferably from 2 to 4; p is an integer from 0 to 2, typically 0 or 1; and q is an integer from 0 to 3, typically 0 or 1.

For example, the compound that is represented by Formula (5b):

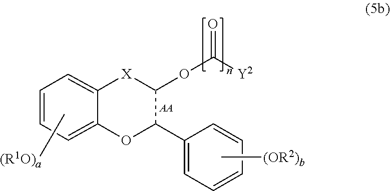

wherein AA, X, R^{A}, R^{B}, R¹, R², Y², a, b, and n are the same as defined for Formula (5a).

In some aspects, the additives of Formula (5), (5a), and/or (5b) may be represented by a compound selected from Formula (5c), Formula (5d), or a combination thereof:

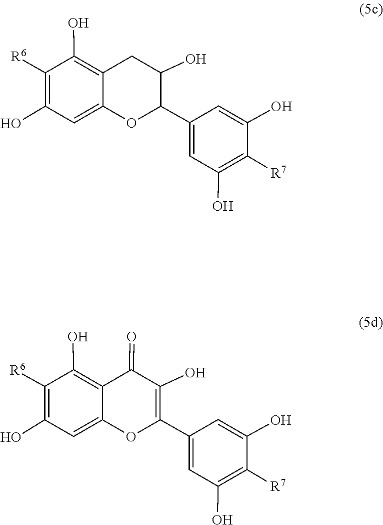

wherein R⁶ is hydrogen, substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; each R^{b} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, substituted or unsubstituted C₁₋₁₀ heteroaryl, or a group of the formula —OR¹; R⁷ is hydrogen, substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; each R^{b} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl, or a group of the formula —OR²; wherein R¹ and R² are the same as defined for Formula (5).

In some aspects, the additives of Formula (5) may be represented by a compound represent by Formula (5e):

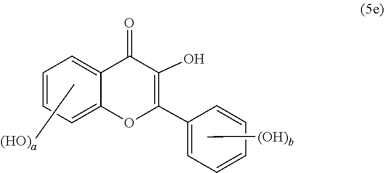

wherein a and b are each independently an integer from 2 to 4, typically 2 or 3.

In some aspects, the additives of Formula (5) may be represented by a compound of Formula (5e), Formula (5f), or a combination thereof:

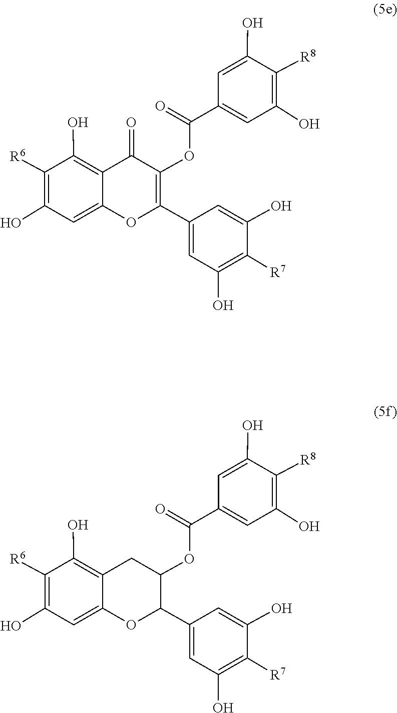

wherein R⁶ is hydrogen or a group of the formula —OR¹; R⁷ is hydrogen or a group of the formula —OR²; and R⁸ is hydrogen, substituted or unsubstituted C₁₋₃₀ alkyl, substituted or unsubstituted C₃₋₃₀ cycloalkyl, —C(O)OR^{5d}, or glycidyl, wherein R^{5d} is hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl; wherein R¹ and R² are the same as defined for Formula (5).

Preferably, the additives of Formula (5) may be represented by a compound of Formula (5g)

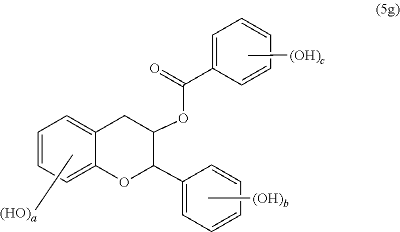

wherein a, b, and c are each independently an integer from 2 to 4, typically 2 or 3.

Exemplary additives of Formula (5) may include one or more compounds selected from:

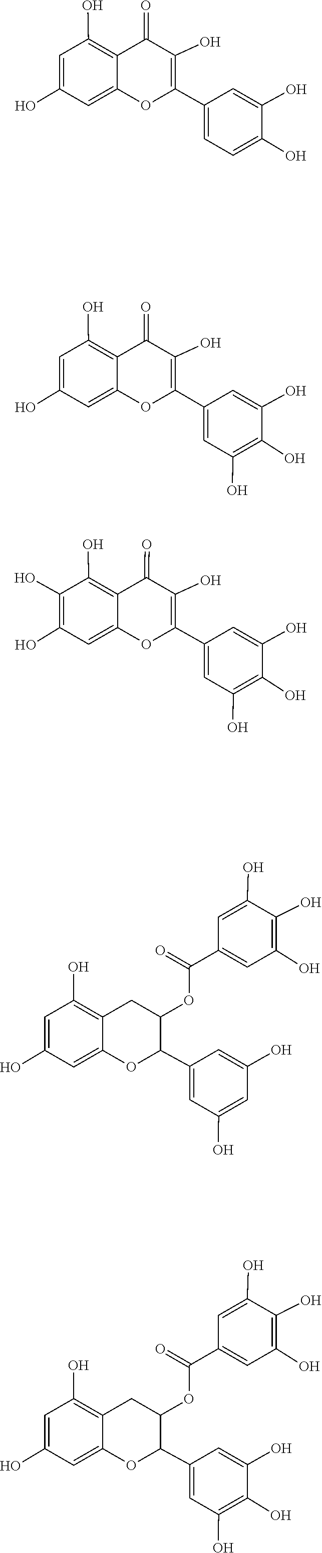 [SMILES: O=c1c(O)c(-c2ccc(O)c(O)c2)oc2cc(O)cc(O)c12 ; O=c1c(O)c(-c2cc(O)c(O)c(O)c2)oc2cc(O)cc(O)c12 ; O=c1c(O)c(-c2cc(O)c(O)c(O)c2)oc2cc(O)c(O)c(O)c12 ; O=C(OC1Cc2c(O)cc(O)cc2OC1c1cc(O)cc(O)c1)c1cc(O)c(O)c(O)c1 ; O=C(OC1Cc2c(O)cc(O)cc2OC1c1cc(O)c(O)c(O)c1)c1cc(O)c(O)c(O)c1]

In some aspects, the additive of Formula (6) may be a compound that is represented Formula (6a):

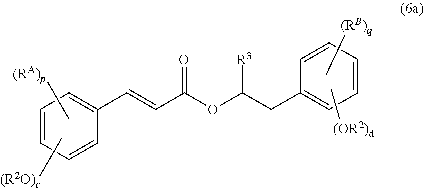

In Formula (6a), R² and R³ are as defined for Formula (6); each R² is independently the same or different from each other R² group; each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; each R^{B} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; c and d are each independently an integer from 2 to 5, typically an integer from 2 to 4; p is an integer from 0 to 2, typically 0 or 1; and q is an integer from 0 to 0 to 3, typically 0 or 1.

For example, the additive of Formula (6) may be a compound that is represented by Formula (6b):

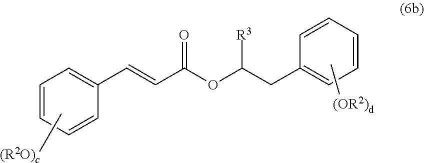

wherein R², R³, c, and d are as defined in Formula (6a).

In some aspects, the additives of Formula (6), (6a), and/or (6b) may be represented by a compound selected from Formula (6c), Formula (6d), or a combination thereof:

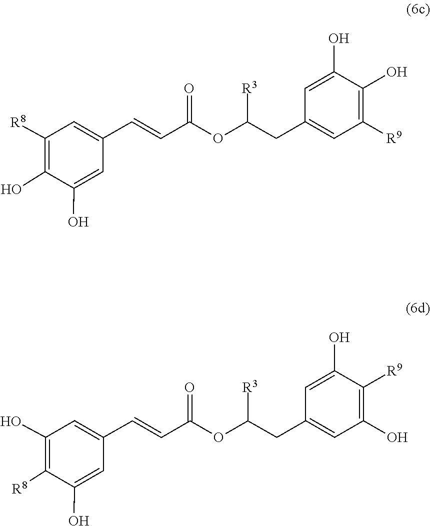

wherein R⁸ is hydrogen, substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; each R^{b} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, substituted or unsubstituted C₁₋₁₀ heteroaryl, or a group of the formula —OR²; R⁹ is hydrogen, substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl; each R^{b} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, substituted or unsubstituted C₁₋₁₀ heteroaryl, or a group of the formula —OR²; wherein each R² is independently the same as defined for Formula (6).

In some aspects, the additives of Formulae (6) may be represented by a compound of Formula (6e):

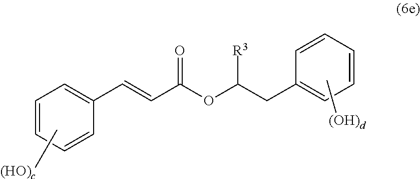

wherein R³ is the same as defined in Formulae (6) and (6b), and c and d are each independently an integer from 2 to 5, typically an integer from 2 to 4.

Exemplary additives of Formula (6) may include one or more compounds selected from:

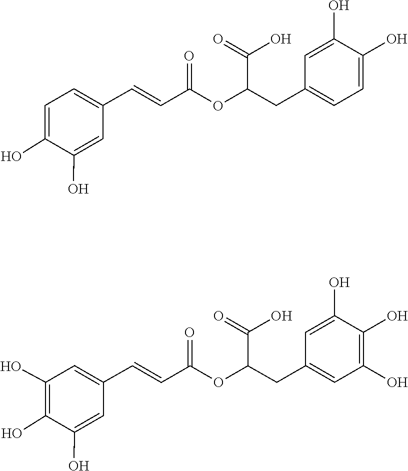 [SMILES: O=C(/C=C/c1ccc(O)c(O)c1)OC(Cc1ccc(O)c(O)c1)C(=O)O ; O=C(/C=C/c1cc(O)c(O)c(O)c1)OC(Cc1cc(O)c(O)c(O)c1)C(=O)O]

The additive may be included in the photoresist underlayer composition in an amount from 0.1 to 20 wt %, typically 1 to 20 wt % or 5 to 20 wt %, based on total solids of the photoresist underlayer composition.

In some aspects, photoresist underlayer composition may further include a polymeric or non-polymeric material that includes a protected amino group as part of its structure. The protected amino group can be derived from a primary or secondary amino moiety. Various amine protecting groups are suitable for use in the present invention, provided such protecting groups are removable (cleavable) by heat, acid, or a combination thereof. Preferably, the amine protecting group is thermally cleavable, such as at a temperature from 75 to 350° C., more preferably from 100 to 300° C., even more preferably from 100 to 250° C.

Suitable amine protecting groups may include carbamates such as 9-fluorenylmethyl carbamates, t-butyl carbamates, and benzyl carbamates; amides such as acetamides, trifluoroacetamides and p-toluenesulfonamides; benzylamines; triphenylmethylamines (tritylamines); and benzylideneamines. Such amine protecting groups, their formation and their removal are well-known in the art. See, for example, T. W. Green et al., Protective Groups in Organic Synthesis, Wiley-Interscience, New York, 1999.

In some aspects, photoresist underlayer composition may include a polymer comprising a protected amino group as part of its structure. For example, the material may be a polymer including a repeating unit derived from a monomer of Formula (7), a repeating unit derived from a monomer of Formula (8), or a combination thereof:

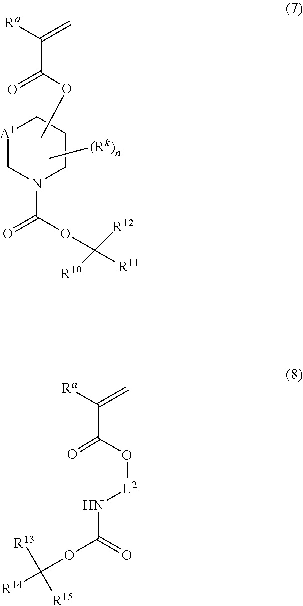

In Formulae (7) and (8), R^{a} may be hydrogen, fluorine, cyano, a substituted or unsubstituted C₁₋₁₀ alkyl, or a substituted or unsubstituted C₁₋₁₀ fluoroalkyl. Preferably, R^{a} is hydrogen, fluorine, or substituted or unsubstituted C₁₋₅ alkyl, typically methyl.

In Formula (7), A¹ is a single bond or substituted or unsubstituted C₁₋₂ alkylene, typically methylene.

In Formula (7), R¹⁰ to R¹² are each independently substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₄₋₂₀ heteroaryl. Optionally, any two of R¹⁰ to R¹² may form a ring together.

In Formula (7), each R^{k} independently may be halogen, hydroxy, carboxylic acid, thiol, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl, wherein R^{k} optionally further comprises one or more of —O—, —C(O)—, —S—, —S(O)—, or —S(O)₂—, wherein R^{7a} is substituted or unsubstituted C₁₋₃₀ alkyl, substituted or unsubstituted C₃₋₃₀ cycloalkyl, substituted or unsubstituted C₁₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₄₋₃₀ heteroaryl, substituted or unsubstituted C₅₋₃₀ heteroarylalkyl, or substituted or unsubstituted C₅₋₃₀ alkylheteroaryl. n is an integer of 0 to 3, typically 0, 1, or 2.

In Formula (8), L² is a divalent linking group, and, for example, may be chosen from one or more of substituted or unsubstituted C₁₋₃₀ alkylene, substituted or unsubstituted C₃₋₃₀ cycloalkylene, substituted or unsubstituted C₂₋₃₀ heterocycloalkylene, substituted or unsubstituted C₆₋₃₀ arylene, substituted or unsubstituted divalent C₇₋₃₀ arylalkyl, substituted or unsubstituted C₁₋₃₀ heteroarylene, or substituted or unsubstituted divalent C₂₋₃₀ heteroarylalkyl, —O—, —C(O)—, —NR^{8a}—, —S—, or —S(O)₂—, wherein R^{8a} is hydrogen, substituted or unsubstituted C₁₋₂₀ alkyl, substituted or unsubstituted C₃₋₂₀ cycloalkyl, substituted or unsubstituted C₂₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, or substituted or unsubstituted C₂₋₃₀ heteroarylalkyl.

In Formula (8), R¹³ to R¹⁵ are each independently substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₄₋₂₀ heteroaryl. Optionally, any two or more of R¹³ to R¹⁵ may form a ring together.

In some aspects, photoresist underlayer composition may include a non-polymeric material that includes a protected amino group. For example, a non-polymeric material that is a compound of Formula (9), a compound of Formula (10), or a combination thereof:

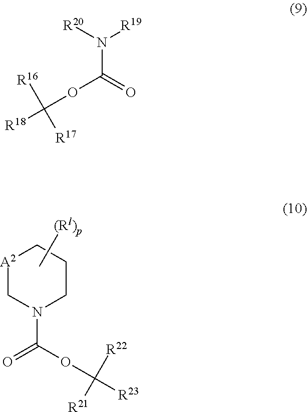

In Formulae (9) and (10), R¹⁶ to R¹⁸ and R²¹ to R²³ may be each independently substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₄₋₂₀ heteroaryl. Optionally, any two or more of R¹⁶ to R¹⁸ together may form a ring. Optionally, any two or more of R²¹ to R²³ together may form a ring.

In Formulae (9), R¹⁹ and R²⁰ are each independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl.

In Formulae (10), A² is a single bond or substituted or unsubstituted C₁₋₂ alkylene, typically methylene. Each R¹ independently may be independently halogen, hydroxy, carboxylic acid, thiol, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl, wherein R¹ optionally further comprises one or more of —O—, —C(O)—, —NR¹⁰a—, —S—, —S(O)—, or —S(O)₂—, wherein R^{10a} is substituted or unsubstituted C₁₋₃₀ alkyl, substituted or unsubstituted C₃₋₃₀ cycloalkyl, substituted or unsubstituted C₁₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₄₋₃₀ heteroaryl, substituted or unsubstituted C₅₋₃₀ heteroarylalkyl, or substituted or unsubstituted C₅₋₃₀ alkylheteroaryl. p may be an integer of 0 to 11. Typically, p may be 0, 1, 2, or 3.

Exemplary groups of the structure represented by —C(R¹⁰)(R¹¹)(R¹²)in Formula (7), the structure represented by —C(R¹³)(R¹⁴)(R¹⁵) of Formula (8), the structure represented by —C(R¹⁶)(R¹⁷)(R¹⁸) of Formula (9), and the structure represented by —C(R²¹)(R²²)(R²³) of Formula (10) may include:

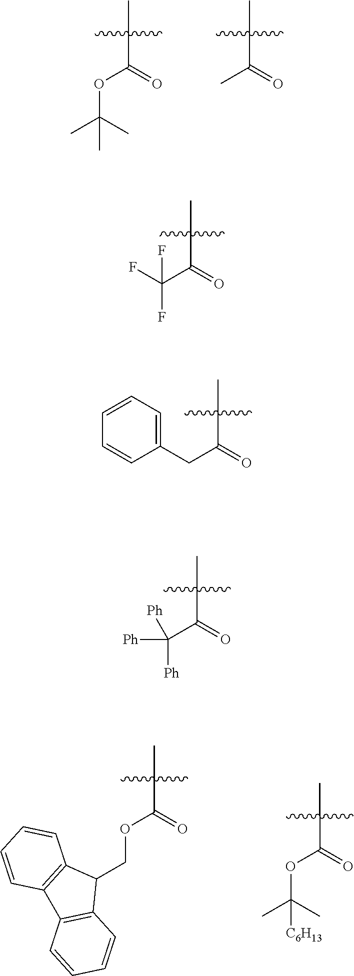

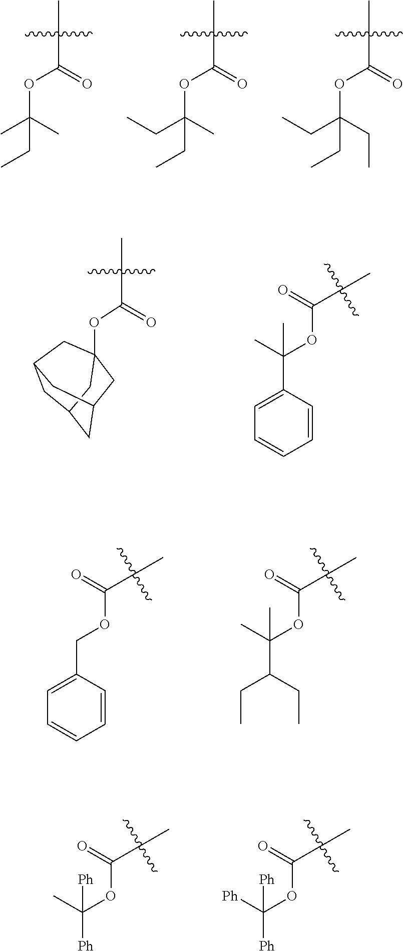

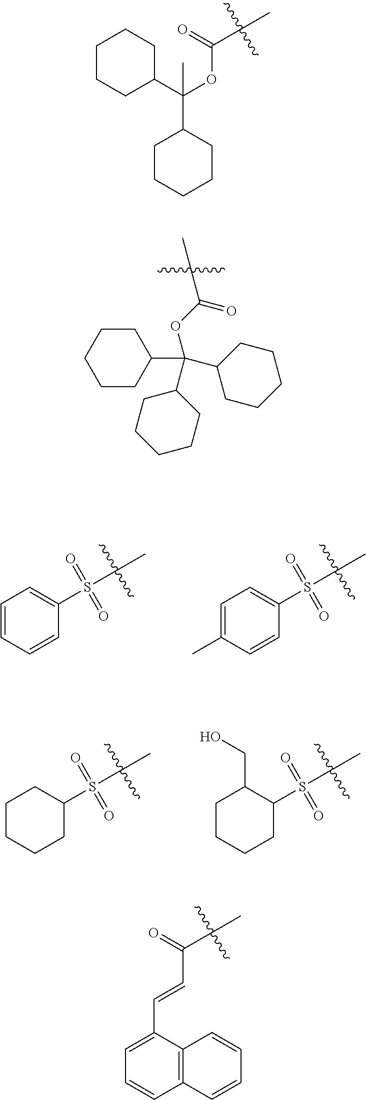

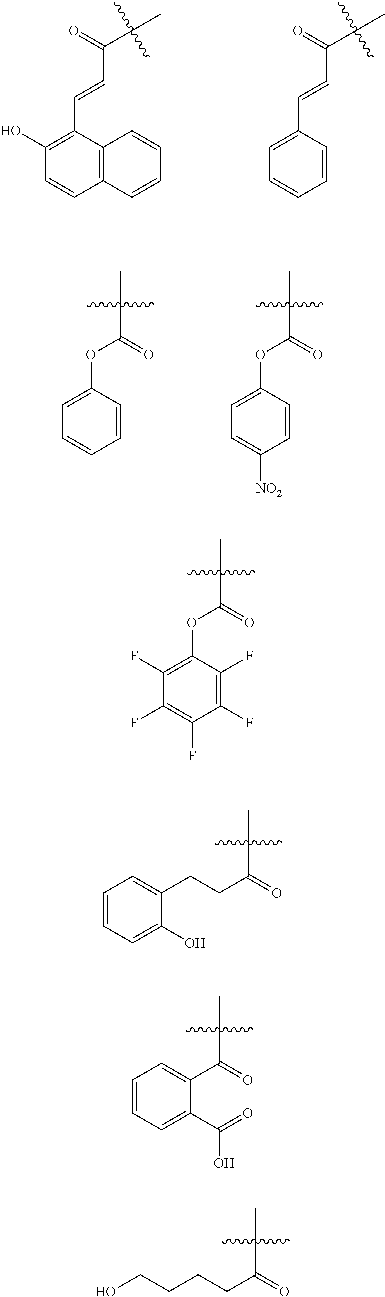

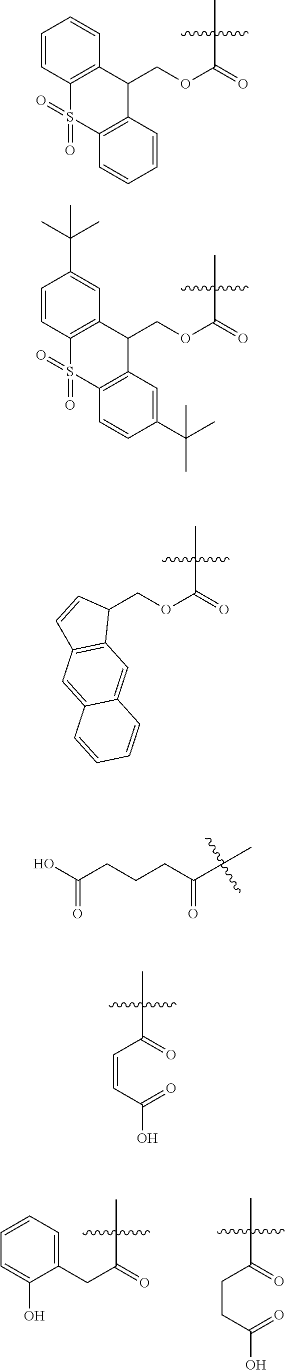

wherein Ph is phenyl.

It is to be understood that the polymers described herein, including a polymer comprising two or more hydroxy groups (e.g., a first polymer), a polymer comprising two or more glycidyl groups (e.g., a second polymer), and a polymer including a repeating unit that is derived from a monomer of Formula (7) and/or a repeating unit that is derived from a monomer of Formula (8) (e.g., a third and/or fourth polymer), each independently may optionally include one or more additional repeating unit(s) different from the repeating units described above. The additional repeating units may include, for example, one or more additional units for purposes of adjusting properties of the photoresist underlayer composition, such as etch rate and solubility. Exemplary additional units may include one or more of (meth)acrylate, vinyl ether, vinyl ketone, and vinyl ester. The one or more additional repeating units if present in the polymer are typically used in an amount of up to 99 mol %, and typically from 3 to 80 mol %, based on total repeating units of the respective polymer.

Suitable polymers of the present invention can be readily prepared based on and by analogy with the procedures described in the examples of the present application, which are readily understood by those of ordinary skill in the art. For example, one or more monomers corresponding to the repeating units described herein may be combined, or fed separately, using suitable solvent(s) and initiator, and polymerized in a reactor. The monomer composition may further include additives, such as a solvent, a polymerization initiator, a curing catalyst (i.e., the acid catalyst), and the like. For example, the polymer may be obtained by polymerization of the respective monomers under any suitable conditions, such as by heating at an effective temperature, irradiation with activating radiation at an effective wavelength, or a combination thereof.

The photoresist underlayer composition may further include one or more polymers (“additional polymers”) in addition to the polymers described above. For example, the photoresist underlayer composition may further include an additional polymer as described above but different in composition. Additionally, or alternatively, the one or more additional polymers can include those well known in the art, for example, one or more polymers selected from polyacrylates, polyvinylethers, polyesters, polynorbornenes, polyacetals, polyethylene glycols, polyamides, polyacrylamides, polyphenols, novolacs, styrenic polymers, polyvinyl alcohols, copolymers thereof, and combination thereof.

The polymers of the invention may have a weight average molecular weight (M_{w}) of 1,000 to 10,000,000 grams per mole (g/mol), more typically 2,000 to 10,000 g/mol, and a number average molecular weight (Mₙ) of 500 to 1,000,000 g/mol. Molecular weights (either M_{w} or Mₙ) are suitably determined by gel permeation chromatography (GPC) using polystyrene standards.

In some aspects, the photoresist underlayer composition may further include one or more curing agents to aid in the curing of the photoresist underlayer composition, for example after the photoresist underlayer composition has been applied to a surface. A curing agent is any component which causes curing of the photoresist underlayer composition on the surface of a substrate.

It may be beneficial to include an acid generator compound such as a photoacid generator (PAG) and/or a thermal acid generator (TAG) compound in the photoresist underlayer compositions. Preferred curing agents are thermal acid generators (TAGs).

Suitable PAGs are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. One or more of such PAGs can be used.

A TAG compound is any compound that liberates acid upon exposure to heat. Exemplary thermal acid generators include, without limitation, amine blocked strong acids, such as amine blocked sulfonic acids such as amine blocked dodecylbenzenesulfonic acid. It will also be appreciated by those skilled in the art that certain photoacid generators are able to liberate acid upon heating and may function as thermal acid generators.

Suitable TAG compounds may include, for example, nitrobenzyl tosylates, such as 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chlorobenzenesulfonate, 2-trifluoromethyl-6-nitrobenzyl 4-nitro benzenesulfonate; phenolic sulfonate esters such as phenyl, 4-methoxybenzenesulfonate; alkyl ammonium salts of organic acids, such as triethylammonium salt of 10-camphorsulfonic acid, trifluoromethylbenzenesulfonic acid, perfluorobutane sulfonic acid; and particular onium salts. A variety of aromatic (anthracene, naphthalene, or benzene derivatives) sulfonic acid amine salts can be employed as the TAG, including those disclosed in U.S. Pat. Nos. 3,474,054, 4,200,729, 4.251,665 and 5,187,019. Examples of TAGs include those sold by King Industries, Norwalk, Conn. USA under NACURE, CDX and K-PURE names, for example, NACURE 5225, CDX-2168E, K-PURE 2678 and KPURE 2700. One or more of such TAGs can be used.

The amount of such curing agents useful in the present compositions may be, for example, from greater than 0 to 10 wt %, and typically from greater than 0 to 3 wt % based on total solids of the photoresist underlayer composition.

In some aspects, the photoresist underlayer composition does not include a photoacid generator. Accordingly, in these embodiments the photoresist underlayer composition may be substantially free of a PAG compound and/or a polymeric PAG, for example free of a PAG compound or polymeric PAG.

The photoresist underlayer composition may further include one or more crosslinking agents, for example a crosslinking agent that includes non-epoxy crosslinkers. Any suitable crosslinking agent may be further used in the present coating compositions, provided that such crosslinking agent has at least 2, and preferably at least 3, moieties capable of reacting with functional groups in the photoresist underlayer composition. Exemplary crosslinking agents may include novolac resins, melamine compounds, guanamine compounds, isocyanate-containing compounds, benzocyclobutenes, benzoxazines, and the like, and typically any of the foregoing having 2 or more, more typically 3 or more substituents selected from methylol, C₁-₁₀alkoxymethyl, and C₂-₁₀ acyloxymethyl. Examples of suitable crosslinking agents include those shown below:

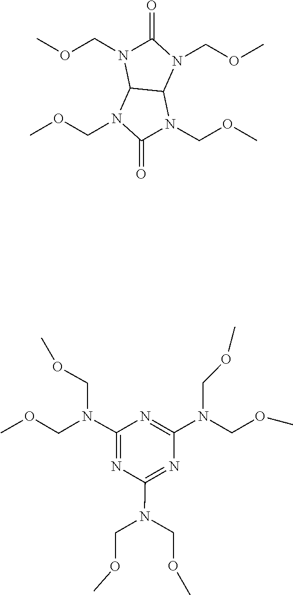

The additional crosslinking agents are well-known in the art and are commercially available from a variety of sources. The amount of such additional crosslinking agents useful in the present coating compositions may be, for example, in the range from greater than 0 to 30 wt %, and preferably from greater than 0 to 10 wt % based on total solids of the coating composition.

The photoresist underlayer composition may include one or more optional additives including, for example, surfactants, antioxidant, or the like, or a combination thereof. When present, each optional additive may be used in the photoresist underlayer composition in minor amounts such as from 0.01 to 10 wt %, based on total solids of the photoresist underlayer composition.

Typical surfactants include those which exhibit an amphiphilic nature, meaning that they may be both hydrophilic and hydrophobic at the same time. Amphiphilic surfactants possess a hydrophilic head group or groups, which have a strong affinity for water and a long hydrophobic tail, which is organophilic and repels water. Suitable surfactants may be ionic (i.e., anionic, cationic) or nonionic. Further examples of surfactants include silicone surfactants, poly(alkylene oxide) surfactants, and fluorochemical surfactants. Suitable non-ionic surfactants include, but are not limited to, octyl and nonyl phenol ethoxylates such as TRITON X-114, X-100, X-45, X-15 and branched secondary alcohol ethoxylates such as TERGITOL TMN-6 (The Dow Chemical Company, Midland, Mich. USA). Still further exemplary surfactants include alcohol (primary and secondary) ethoxylates, amine ethoxylates, glucosides, glucamine, polyethylene glycols, poly(ethylene glycol-co-propylene glycol), or other surfactants disclosed in McCutcheon's Emulsifiers and Detergents, North American Edition for the Year 2000 published by Manufacturers Confectioners Publishing Co. of Glen Rock, N.J. Nonionic surfactants that are acetylenic diol derivatives also may be suitable. Such surfactants are commercially available from Air Products and Chemicals, Inc. of Allentown, Pa. and sold under the trade names of SURFYNOL and DYNOL. Additional suitable surfactants include other polymeric compounds such as the tri-block EO-PO-EO co-polymers PLURONIC 25R2, L121, L123, L31, L81, L101, and P123 (BASF, Inc.).

An antioxidant can be added to prevent or minimize oxidation of organic materials in the photoresist underlayer composition. Suitable antioxidants include, for example, phenol-based antioxidants, antioxidants composed of an organic acid derivative, sulfur-containing antioxidants, phosphorus-based antioxidants, amine-based antioxidants, antioxidant composed of an amine-aldehyde condensate and antioxidants composed of an amine-ketone condensate. Examples of the phenol-based antioxidant include substituted phenols such as 1-oxy-3-methyl-4-isopropylbenzene, 2,6-di-tert-butylphenol, 2,6-di-tert-butyl-4-ethylphenol, 2,6-di-tert-butyl-4-methylphenol, 4-hydroxymethyl-2,6-di-tert-butylphenol, butyl.hydroxyanisole, 2-(1-methylcyclohexyl)-4,6-dimethylphenol, 2,4-dimethyl-6-tert-butylphenol, 2-methyl-4,6-dinonylphenol, 2,6-di-tert-butyl-α-dimethylamino-p-cresol, 6-(4-hydroxy-3,5-di-tert-butyl.anilino)2,4-bis.octyl-thio-1,3,5-triazine, n-octadecyl-3-(4′-hydroxy-3′,5′-di-tert-butyl.phenyl)propionate, octylated phenol, aralkyl-substituted phenols, alkylated p-cresol and hindered phenol; bis-, tris- and poly-phenols such as 4,4′-bisphenol, 4,4′-methylene-bis-(dimethyl-4,6-phenol), 2,2′-methylene-bis-(4-methyl-6-tert-butylphenol), 2,2′-methylene-bis-(4-methyl-6-cyclohexylphenol), 2,2′-methylene-bis-(4-ethyl-6-tert-butylphenol), 4,4′-methylene-bis-(2,6-di-tert-butylphenol), 2,2′-methylene-bis-(6-α-methyl-benzyl-p-cresol), methylene-crosslinked polyvalent alkylphenol, 4,4′-butylidene-bis-(3-methyl-6-tert-butylphenol), 1,1-bis-(4-hydroxyphenyl)-cyclohexane, 2,2′-dihydroxy-3,3′-di-(α-methylcyclohexyl)-5,5′-dimethyl.diphenylmethane, alkylated bisphenol, hindered bisphenol, 1,3,5-trimethyl-2,4,6-tris(3,5-di-tert-butyl-4-hydroxybenzyl)benzene, tris-(2-methyl-4-hydroxy-5-tert-butylphenyl)butane, and tetrakis-[methylene-3-(3′,5′-di-tert-butyl-4′-hydroxyphenyl)propionate]methane. Suitable antioxidants are commercially available, for example, Irganox™ antioxidants (Ciba Specialty Chemicals Corp.).

The photoresist underlayer composition includes a solvent. The solvent component may be a single solvent or may include a mixture of two or more distinct solvents. Suitably, each of the multiple solvents may be miscible with each other. Suitable solvents include, for example, one or more oxyisobutyric acid esters, particularly methyl-2-hydroxyisobutyrate, 2-hydroxyisobutyric acid, and ethyl lactate; one or more of glycol ethers, particularly 2-methoxyethyl ether (diglyme), ethylene glycol monomethyl ether, and propylene glycol monomethyl ether; one or more solvents that have both ether and hydroxy moieties, particularly methoxy butanol, ethoxy butanol, methoxy propanol, and ethoxy propanol; one or more alkyl esters, particularly methyl cellosolve acetate, ethyl cellosolve acetate, propylene glycol monomethyl ether acetate, and dipropylene glycol monomethyl ether acetate and other solvents such as one or more dibasic esters; and/or other solvents such as one or more of propylene carbonate and gamma-butyro lactone.

The desired total solids of the photoresist underlayer composition will depend on factors such as the desired final layer thickness. Typically, the total solids of the photoresist underlayer composition may be from 0.1 to 20 wt %, for example, from 0.1 to 10 wt %, more typically, from 0.11 to 5 wt %, based on the total weight of the coating composition.

The photoresist underlayer composition may be prepared following known procedures. For example, the photoresist underlayer composition may be prepared by combining the first material, the second material, the additive, the solvent, and any optional components, in any order. The photoresist underlayer composition may be used as is, or may be subjected to purification or dilution prior to being coated on the substrate. Purification may involve, for example, one or more of centrifugation, filtration, distillation, decantation, evaporation, treatment with ion exchange beads, and the like.

The patterning methods of the present invention comprise applying a layer of the photoresist underlayer composition over a substrate; curing the applied photoresist underlayer composition to form a coated underlayer; and forming a photoresist layer over the coated underlayer. The method may further include the steps of pattern-wise exposing the photoresist layer to activating radiation; and developing the exposed photoresist layer to provide a resist relief image. In some aspects, the method may further include forming a silicon-containing layer, an organic antireflective coating layer, or a combination thereof, over the coated underlayer prior to forming the photoresist layer. In some aspects, the method may further include transferring the pattern to the silicon-containing layer, the organic antireflective coating layer, or the combination thereof, after developing an exposed photoresist layer and before the step transferring the pattern to the coated underlayer.

A wide variety of substrates may be used in the patterning methods, with electronic device substrates being typical. Suitable substrates include, for example, packaging substrates such as multichip modules; flat panel display substrates; integrated circuit substrates; substrates for light emitting diodes (LEDs) including organic light emitting diodes (OLEDs); semiconductor wafers; polycrystalline silicon substrates; and the like. Suitable substrates may be in the form of wafers such as those used in the manufacture of integrated circuits, optical sensors, flat panel displays, integrated optical circuits, and LEDs. As used herein, the term “semiconductor wafer” is intended to encompass “an electronic device substrate,” “a semiconductor substrate,” “a semiconductor device,” and various packages for various levels of interconnection, including a single-chip wafer, multiple-chip wafer, packages for various levels, or other assemblies requiring solder connections. Such substrates may be any suitable size. Typical wafer substrate diameters are 200 mm to 300 mm, although wafers having smaller and larger diameters may be suitably employed according to the present invention. As used herein, the term “semiconductor substrate” includes any substrate having one or more semiconductor layers or structures which may optionally include active or operable portions of semiconductor devices. A semiconductor device refers to a semiconductor substrate upon which at least one microelectronic device has been or is being batch fabricated.

The substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. The substrate may include one or more layers and patterned features. The layers may include, for example, one or more conductive layers such as layers of aluminum, copper, molybdenum, tantalum, titanium, tungsten, alloys, nitrides, or silicides of such metals, doped amorphous silicon or doped polysilicon, one or more dielectric layers such as layers of silicon oxide, silicon nitride, silicon oxynitride, or metal oxides, semiconductor layers, such as single-crystal silicon, and combinations thereof. In some aspects, the substrate includes titanium nitride. The layers can be formed by various techniques, for example, chemical vapor deposition (CVD) such as plasma-enhanced CVD (PECVD), low-pressure CVD (LPCVD) or epitaxial growth, physical vapor deposition (PVD) such as sputtering or evaporation, or electroplating.

It may be desired in certain patterning methods of the invention to provide one or more lithographic layers such as a hardmask layer, for example, a spin-on-carbon (SOC), amorphous carbon, or metal hardmask layer, a CVD layer such as a silicon nitride (SiN) layer, silicon oxide (SiO) layer, or silicon oxynitride (SiON) layer, an organic or inorganic BARC layer, or a combination thereof, on an upper surface of the substrate prior to forming the photoresist underlayer of the invention. Such layers, together with a layer of the photoresist underlayer composition of the invention and photoresist layer, form a lithographic material stack. Typical lithographic stacks which may be used in the patterning methods of the invention include, for example, the following: SOC layer/underlayer/photoresist layer; SOC layer/SiON layer/underlayer/photoresist layer; SOC layer/SiARC layer/underlayer/photoresist layer; SOC layer/metal hardmask layer/underlayer/photoresist layer; amorphous carbon layer/underlayer/photoresist layer; and amorphous carbon layer/SiON layer/underlayer/photoresist layer.

It is to be understood that the “photoresist underlayer,” as used herein, refers to the one or more layers that are disposed between the substrate and the photoresist layer (i.e., “above the substrate”). Accordingly, the inventive coated underlayer (i.e., a layer of the photoresist underlayer composition) may be used alone as a photoresist underlayer, or the inventive coated underlayer (i.e., a layer of the photoresist underlayer composition) may be used in conjunction with other underlayers, including those as described herein.

The photoresist underlayer composition may be coated on the substrate by any suitable means, such as spin-coating, slot-die coating, doctor blading, curtain-coating, roller-coating, spray-coating, dip-coating, and the like. In the case of a semiconductor wafer, spin-coating is preferred. In a typical spin-coating method, the present compositions are applied to a substrate which is spinning at a rate of 500 to 4000 revolutions per minute (rpm) for a period of 15 to 90 seconds to obtain a desired layer of the condensed polymer on the substrate. It will be appreciated by those skilled in the art that the thickness of the coated layer may be adjusted by changing the spin speed, as well as the solids content of the composition. An underlayer formed from the photoresist underlayer composition typically has a dried layer thickness from 1 to 50 nanometers (nm), more typically from 1 to 10 nm.

The coated photoresist underlayer composition is optionally softbaked at a relatively low temperature to remove any solvent and other relatively volatile components. Typically, the substrate is baked at a temperature of less than or equal to 150° C., preferably from 60 to 125° C., and more preferably from 90 to 115° C. The baking time is typically from 10 seconds to 10 minutes, preferably from 30 seconds to 5 minutes, and more preferably from 6 to 90 seconds. When the substrate is a wafer, such baking step may be performed by heating the wafer on a hot plate. Such soft-baking step may be performed as part of the curing of the coating layer, or may be omitted altogether.

The photoresist underlayer composition is then cured to form a coated underlayer. The coating composition should be sufficiently cured such that the coated underlayer film does not intermix, or minimally intermixes, with another underlayer component or the photoresist layer to be formed above the underlayer. The coated composition may be cured in an oxygen-containing atmosphere, such as air, or in an inert atmosphere, such as nitrogen and under conditions, such as heating, sufficient to provide a cured coating layer. This curing step is preferably conducted on a hot plate-style apparatus, although oven curing may be used to obtain equivalent results. Typically, the curing may be conducted at a temperature of 150° C. or greater, and preferably 150 to 450° C. It is more preferred that the curing temperature is 180° C. or greater, still more preferably 200° C. or greater, and even more preferably from 200 to 400° C. The curing time is typically from 10 seconds to 10 minutes, preferably from 30 seconds to 5 minutes, more preferably from 45 seconds to 2 minutes, and still more preferably from 45 to 90 seconds. Optionally, a ramped or a multi-stage curing process may be used. A ramped bake typically begins at a relatively low (e.g., ambient) temperature that is increased at a constant or varied ramp rate to a higher target temperature. A multi-stage curing process involves curing at two or more temperature plateaus, typically a first stage at a lower bake temperature and one or more additional stages at a higher temperature. Conditions for such ramped or multi-stage curing processes are known to those skilled in the art, and may allow for omission of a preceding softbake process.

After curing of the applied photoresist underlayer composition, a photoresist layer is formed over the coated underlayer. As noted above, other intervening layers may be applied between the coated underlayer and the overcoated photoresist layer. In some aspect, the method may further include forming a silicon-containing layer, an organic antireflective coating layer, or a combination thereof, over the coated underlayer prior to forming the photoresist layer.

A wide variety of photoresists may be suitably used in the methods of the invention and are typically positive-tone materials. The particular photoresists to be used will depend on the exposure wavelength used and generally comprise an acid-sensitive matrix polymer, a photoactive component such as a photoacid generator, a solvent, and optional additional components. Suitable photoresists are known to those skilled in the art and are commercially available, for example, various photoresist materials in the UV™ and EPIC™ product families from DuPont Electronics & Imaging. The photoresist can be applied to the substrate by known coating techniques such as described above with reference to the underlayer composition, with spin-coating being typical. A typical thickness for the photoresist layer is from 10 to 300 nm. The photoresist layer is typically next softbaked to minimize the solvent content in the layer, thereby forming a tack-free coating and improving adhesion of the layer to the substrate. The softbake can be conducted on a hotplate or in an oven, with a hotplate being typical. Typical softbakes are conducted at a temperature from 70 to 150° C., and a time from 30 to 90 seconds.

The photoresist layer is next exposed to activating radiation through a photomask to create a difference in solubility between exposed and unexposed regions. References herein to exposing a photoresist composition to radiation that is activating for the composition indicates that the radiation is capable of forming a latent image in the photoresist composition. The photomask has optically transparent and optically opaque regions corresponding to regions of the resist layer to be exposed and unexposed, respectively, by the activating radiation. The exposure wavelength is typically sub-400 nm, and more typically, sub-300 nm, such as 248 nm (KrF), 193 nm (ArF), or an EUV wavelength (e.g., 13.5 nm). In a preferred aspect, the exposure wavelength is 193 nm or an EUV wavelength. The exposure energy is typically from 10 to 100 millijoules per square centimeter (mJ/cm²), depending, for example, on the exposure tool and the components of the photosensitive composition.

Following exposure of the photoresist layer, a post-exposure bake (PEB) is typically performed. The PEB can be conducted, for example, on a hotplate or in an oven. The PEB is typically conducted at a temperature from 70 to 150° C., and a time from 30 to 90 seconds. A latent image defined by the boundary between polarity-switched and unswitched regions (corresponding to exposed and unexposed regions, respectively) is thereby formed. The photoresist layer is next developed to remove the exposed regions of the layer, leaving the unexposed regions forming a patterned photoresist layer. The developer is typically an aqueous alkaline developer, for example, a tetra-alkyl ammonium hydroxide solution such as a tetramethylammonium hydroxide (TMAH) solution, typically a 0.26 Normality (N) (2.38 wt %) solution of TMAH. The developer may be applied by known techniques, for example, spin-coating or puddle coating.

The pattern of the photoresist layer can be transferred to one or more underlying layers including the coated underlayer and to the substrate by appropriate etching techniques, such as by plasma etching using appropriate gas species for each layer being etched. Depending on the number of layers and materials involved, pattern transfer may include multiple etching steps using different etching gases. The patterned photoresist layer, the coated underlayer, and the other optional layers in the lithographic stack may be removed following pattern transfer to the substrate using conventional techniques. Optionally, one or more of the layers of the stack may be removed following, or consumed during, pattern transfer to an underlying layer and prior to pattern transfer to the substrate. For example, pattern transfer to one or more of a silicon-containing layer, an organic antireflective coating layer, or the like may occur after the exposed photoresist layer is developed and before pattern transfer to the coated underlayer. The substrate is then further processed according to known processes to form an electronic device.

Also provided is a coated substrate that includes a layer of the inventive photoresist underlayer composition on a substrate; and a photoresist layer disposed on the layer of the photoresist underlayer composition. As used herein, the term “cured layer” refers to a layer derived from the photoresist underlayer composition after the composition has been disposed on a substrate and subsequently cured to form a coating layer or film. In other words, curing the photoresist underlayer composition forms a cured layer derived from the photoresist underlayer composition.

Still other aspects provide a layered article including a coated underlayer derived from the inventive photoresist underlayer composition. In an embodiment, a layered article may include a substrate; a coated underlayer disposed over the substrate; and a photoresist layer disposed over the coated underlayer.

Photoresist underlayers, including coated underlayers prepared from the inventive photoresist underlayer composition show excellent photospeed and improved pattern collapse. Preferred photoresist underlayer compositions of the invention may, as a result, be useful in a variety of semiconductor manufacturing processes

The present inventive concept is further illustrated by the following examples, which are intended to be non-limiting. The compounds and reagents used herein are available commercially except where a procedure is provided below.

### EXAMPLES

The structures of the compounds and polymers used in the Examples are shown below:

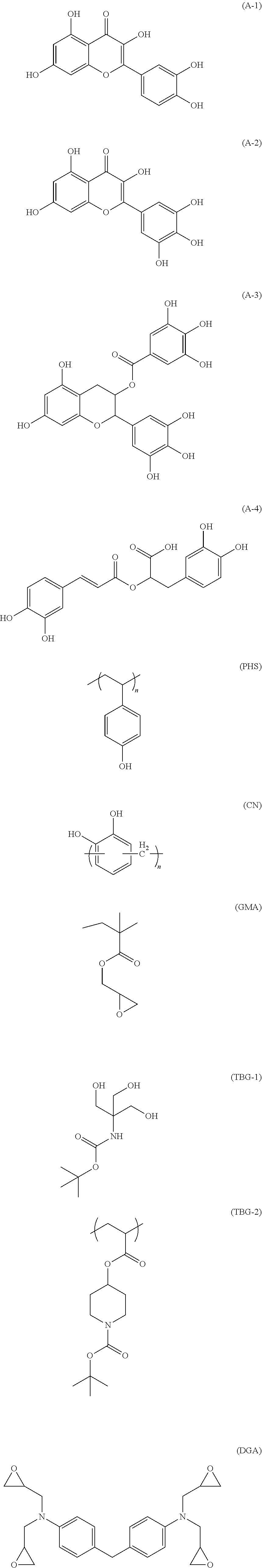

### Underlayer Compositions

Table 1 shows the coating compositions for Examples 1 to 17 and Comparative Examples 1 to 3 that were prepared by mixing the components in the amounts shown. The amounts in parenthesis are in weight percent based on the total weight of the coating composition including Material 1, Material 2, the additive compound, the thermal base generator (TBG) compound, and the solvent(s).

TABLE 1

| | Material 1 | Material 2 | Additive | TBG | Solvent(s) |
|---|---|---|---|---|---|
| Example 1 | CN (1.7) | GMA (2.3) | A-1 (0.4) | — | PGMEA (95.6) |
| Example 2 | CN (1.6) | DGA (2.0) | A-1 (0.4) | — | PGMEA (48.0)/PGME (48.0) |
| Example 3 | CN (1.7) | GMA (2.3) | A-1 (0.4) | TBG-1 (0.4) | PGMEA (95.2) |
| Example 4 | CN (1.7) | GMA (2.3) | A-1 (0.4) | TBG-2 (0.4) | PGMEA (95.2) |
| Example 5 | CN (1.7) | GMA (2.3) | A-2 (0.4) | — | PGME (95.6) |
| Example 6 | CN (1.7) | GMA (2.3) | A-2 (0.4) | TBG-2 (0.4) | PGMEA (95.2) |
| Example 7 | CN (1.7) | GMA (2.3) | A-3 (0.4) | — | PGMEA (95.6) |
| Example 8 | CN (1.7) | GMA (2.3) | A-4 (0.4) | — | PGMEA (47.8)/PGME (47.8) |
| Example 9 | CN (0.9) | GMA (1.1) | A-4 (2.0) | — | PGMEA (48.0)/PGME (48.0) |
| Example 10 | CN (1.6) | DGA (2.0) | A-4 (0.4) | — | PGMEA (48.0)/PGME (48.0) |
| Example 11 | CN (1.7) | GMA (2.3) | A-4 (0.4) | TBG-2 (0.4) | PGMEA (47.6)/PGME (47.6) |
| Example 12 | PHS (2.0) | GMA (2.0) | A-1 (0.4) | — | PGMEA (47.8)/PGME (47.8) |
| Example 13 | PHS (1.6) | DGA (2.0) | A-1 (0.4) | — | PGMEA (48.0)/PGME (48.0) |
| Example 14 | PHS (2.0) | GMA (2.0) | A-2 (0.4) | — | PGMEA (47.8)/PGME (47.8) |
| Example 15 | PHS (2.0) | GMA (2.0) | A-3 (0.4) | — | PGMEA (47.8)/PGME (47.8) |
| Example 16 | PHS (2.0) | GMA (2.0) | A-4 (0.4) | — | PGMEA (47.8)/PGME (47.8) |
| Example 17 | PHS (1.6) | DGA (2.0) | A-4 (0.4) | — | PGMEA (48.0)/PGME (48.0) |
| Comparative | CN (1.7) | GMA (2.3) | — | — | PGMEA (96.0) |
| Example 1 | | | | | |
| Comparative | CN (4.0) | — | — | — | PGMEA (96.0) |
| Example 2 | | | | | |
| Comparative | PHS (2.0) | GMA (2.0) | — | — | PGMEA (96.0) |
| Example 3 | | | | | |

The following abbreviations are used in Table 1: PHS=poly(hydroxystyrene) (M_{w} (GPC)=4,299 g/mol, Waco chemical); CN=catechol novolac (M_{w} (GPC)=2,290 g/mol); GMA=poly(glycidyl methacrylate) (M_{w} (GPC)=3,922 g/mol); DGA=4,4′-methylenebis(N,N-diglycidylaniline); PGMEA=propylene glycol methyl ether acetate; and PGME=propylene glycol methyl ether.

### Solvent Strip Resistance Evaluation

Each of the compositions in Table 1 was filtered through a 0.2 μm polytetrafluoroethylene syringe filter and spin-coated onto respective bare 200-mm silicon wafers on an ACT-8 Clean Track (Tokyo Electron Co.) at 1500 rpm, and then cured at 215° C. for 60 seconds to form a cured coating layer as a film. The initial film thickness was measured with a Therma-Wave OptiProbe™ metrology tool. Solvent strip resistance was determined by applying a PGMEA remover to each of the respective films for 90 seconds followed by a post-strip bake at 105° C. for 60 seconds. The thickness of each respective film was again measured to determine the amount of film thickness that was lost by the application of the PGMEA remover. Table 2 shows the results for film thickness measurements before and after contact with the PGMEA remover, where the results are expressed as the percentage of film thickness remaining on the wafer after contact with the PGMEA remover (% Film Remaining). The amount of film remaining after treatment with the PGMEA remover was indicative of the degree of crosslinking of the cured coating layer.

TABLE 2

| | Film remaining (%) |
|---|---|
| Example 1 | 100.0 |
| Example 2 | 99.9 |
| Example 3 | 100.0 |
| Example 4 | 99.4 |
| Example 5 | 99.9 |
| Example 6 | 99.3 |
| Example 7 | 99.9 |
| Example 8 | 100.0 |
| Example 9 | 100.0 |
| Example 10 | 100.0 |
| Example 11 | 99.3 |
| Example 12 | 99.9 |
| Example 13 | 99.9 |
| Example 14 | 99.9 |
| Example 15 | 100.0 |
| Example 16 | 99.9 |
| Example 17 | 99.9 |
| Comparative Example 1 | 99.9 |
| Comparative Example 2 | 0.0 |
| Comparative Example 3 | 99.9 |

### Wet Strip Evaluation

Each of the compositions in Table 1 was filtered through a 0.2 μm polytetrafluoroethylene syringe filter and spin-coated onto respective wafers (silicon wafers coated with a TiN film having a thickness of 9 nm that is prepared using an atomic layer deposition method) at 1500 rpm and baked at 215° C. for 60 seconds using an ACT-8 Clean Track (Tokyo Electron Co.). Film thickness after baking of each coated film (ca. 900 Å) was measured with an OptiProbe™ instrument from Therma-wave Co. The coated sample was then evaluated for SC-1 wet strippability using a mixture of 30% NH₄OH/30% H₂O₂/water in a w/w/w ratio of 1:1:5. The SC-1 mixture then was heated to 50° C. Coupons of each coated wafer were immersed into the stripping solution for 2, 5, and 8 minutes. The coupons were removed from the SC-1 mixture after the specified time and rinsed with deionized water. The film quality of the samples are provided based on immersion times (2, 5, and 8 minutes) in Table 3, where visual inspection was used to evaluate the samples as described below.

TABLE 3

| | SC-1 | SC-1 | SC-1 |
|---|---|---|---|
| | Resistance | Resistance | Resistance |
| | (2 minutes) | (5 minutes) | (8 minutes) |
| Example 1 | A | A | A |
| Example 2 | A | A | B |
| Example 3 | A | A | A |
| Example 4 | A | A | A |
| Example 5 | A | B | B |
| Example 6 | A | B | B |
| Example 7 | A | A | B |
| Example 8 | A | A | A |
| Example 9 | A | A | A |
| Example 10 | A | A | A |
| Example 11 | A | A | A |
| Example 12 | A | C | — |
| Example 13 | A | A | A |
| Example 14 | A | C | — |
| Example 15 | A | C | — |
| Example 16 | A | A | A |
| Example 17 | A | A | A |
| Comparative Example 1 | A | C | — |
| Comparative Example 2 | C | — | — |
| Comparative Example 3 | B | C | — |

For the evaluations in Table 4, the following abbreviations are used: A: Pristine film, B: partial film degradation, C: fully delaminated film. Each sample was evaluated using visible inspection by eye.

As can be seen from Table 3, the samples of Examples 1 to 17 that include the respective additive compound began to delaminate at later times in the SC-1 bath compared to the samples prepared from the Comparative Examples and without the additive. The samples of Examples 1, 3, 4, 8-11, 13, 16, and 17 were pristine after 2, 5, and 8 minutes in the SC-1 bath. The samples of Examples 5 and 6 show only partial film delamination after 5 minutes in the SC-1 bath, while the sample of Comparative Example 1 is fully delaminated after 5 minutes in the SC-1 bath. Additionally, Examples 12, 14, and 15 are pristine after 2 minutes in the SC-1 bath, whereas Comparative Example 3 is partially delaminated after 2 minutes in the SC-1 bath.

### Post SC-1 Underlayer Pattern Profile Evaluation

Samples of Example 1 and Comparative Example 1 were spin-coated onto respective wafers (silicon wafers coated with a TiN film having a thickness of 9 nm that is prepared using an atomic layer deposition method) at 1500 rpm, and then cured at 215° C. for 60 seconds to form a film having a thickness of 900 Å. Coupons of each coated wafer were etched with O₂ for 25 seconds. After the etch back process, the coupons were immersed in a mixture of 30% NH₄OH/30% H₂O₂/water in a w/w/w ratio of 1:1:5. The SC-1 mixture then was heated to 50° C. for five minutes. XSEM images were obtained for each sample, both after O₂ etching and after SC-1 treatment. The results are shown in Table 4, where the film profile is described as standing or collapsed.

TABLE 4

| | Film shape | Film shape |
|---|---|---|
| | (after O₂ etching) | (after SC-1 treatment) |
| Example 1 | Standing | Standing |
| Comparative Example 1 | Standing | Collapsed |

As shown by the results in Table 4, the sample of Example 1 maintained film shape after O₂ etching and after SC-1 treatment. In contrast, the sample of Comparative Example 1 only maintained film shape after O₂ etching, whereas the film profile was collapsed after SC-1 treatment. The results show that the inventive photoresist underlayer composition can provide improved resilience to the damaging effects of SC-1 treatment.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A photoresist underlayer composition, comprising:
a first material comprising two or more hydroxy groups;
a second material comprising two or more glycidyl groups;
an additive, wherein the additive comprises a compound of Formula (5), a compound of Formula (6), or a combination thereof; and
a solvent, 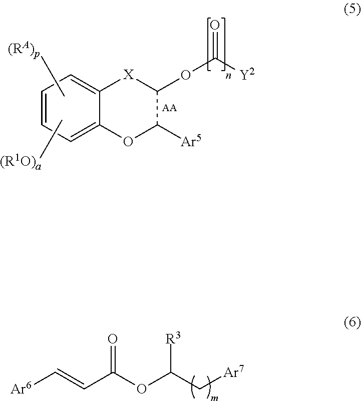
wherein, in Formulae (5) and (6),
AA represents a single bond or a double bond;
X is a single bond, —C(O)—, unsubstituted C₁ alkylene, or hydroxy-substituted C₁ alkylene;
Ar⁵, Ar⁶, and Ar⁷ are each independently C₆₋₆₀ aryl or C₁₋₆₀ heteroaryl;
wherein Ar⁵, Ar⁶, and Ar⁷ are each independently substituted with at least two groups of formula —OR²;
optionally, wherein Ar⁵, Ar⁶, and Ar⁷ are each independently further substituted;
R¹ and R² are each independently hydrogen, substituted or unsubstituted C₁₋₃₀ alkyl, substituted or unsubstituted C₃₋₃₀ cycloalkyl, —C(O)OR^{5a}, or glycidyl;
each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{5a} is independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
R³ is hydrogen, substituted or unsubstituted C₁₋₃₀ alkyl, substituted or unsubstituted C₃₋₃₀ cycloalkyl, substituted or unsubstituted C₁₋₃₀ heterocycloalkyl, a carboxylic acid group or a derivative thereof, or —C(O)OR^{5b};
R^{5b} is substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
a is an integer from 2 to 4;
m is an integer from 1 to 6;
n is 0 or 1;
p is an integer from 0 to 2; and
Y² is hydrogen, substituted or unsubstituted C₆₋₆₀ aryl, or substituted or unsubstituted C₁₋₆₀ heteroaryl.

2. The photoresist underlayer composition of claim 1, wherein the additive comprises a compound represented by Formula (5a): 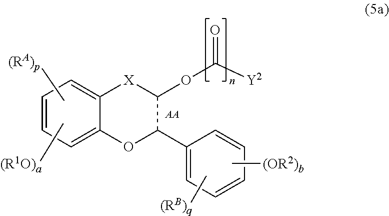
wherein, in Formulae (5a),
AA represents a single bond or a double bond;
X is a single bond, —C(O)—, unsubstituted C₁ alkylene, or hydroxy-substituted C₁ alkylene;
R¹ and R² are each independently hydrogen, substituted or unsubstituted C₁₋₃₀ alkyl, substituted or unsubstituted C₃₋₃₀ cycloalkyl, —C(O)OR^{5a}, or glycidyl;
each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{B} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each lea iₛ independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
a is an integer from 2 to 4;
b is an integer from 2 to 5;
n is 0 or 1;
p is an integer from 0 to 2;
q is an integer from 0 to 3; and
Y² is hydrogen, substituted or unsubstituted C₆₋₆₀ aryl, or substituted or unsubstituted C₁₋₆₀ heteroaryl.

3. The photoresist underlayer composition of claim 1, wherein the additive comprises a compound represented by Formula (6a): 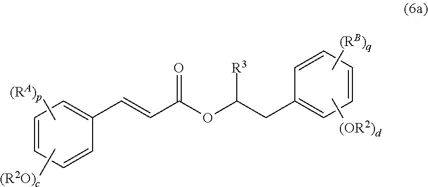
wherein, in Formulae (6a),
each R² is independently hydrogen, substituted or unsubstituted C₁₋₃₀ alkyl, substituted or unsubstituted C₃₋₃₀ cycloalkyl, —C(O)R^{5a}, or glycidyl;
each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{B} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{5a} is independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
R³ is hydrogen, substituted or unsubstituted C₁₋₃₀ alkyl, substituted or unsubstituted C₃₋₃₀ cycloalkyl, substituted or unsubstituted C₁₋₃₀ heterocycloalkyl, a carboxylic acid group or a derivative thereof, or —C(O)OR^{5b};
R^{5b} is substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
c is an integer from 2 to 5;
d is an integer from 2 to 5;
p is an integer from 0 to 2; and
q is an integer from 0 to 3.

4. The photoresist underlayer composition of claim 1, further comprising a third polymer comprising a repeating unit derived from a monomer of Formulae (7), (8), or a combination thereof: 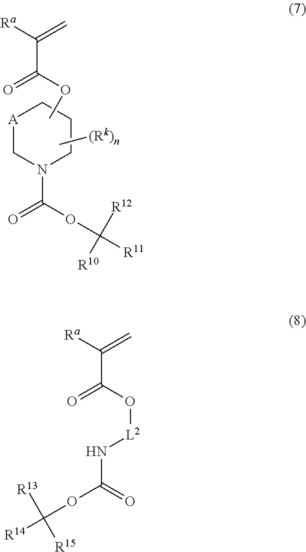
wherein, in Formulae (7) and (8),
each R^{a} is independently hydrogen, fluorine, a substituted or unsubstituted C₁₋₅ alkyl, or a substituted or unsubstituted C₁₋₅ fluoroalkyl;
A is a single bond or substituted or unsubstituted C₁₋₂ alkylene;
each R^{k} is independently halogen, hydroxyl, carboxyl, thiol, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl, wherein R^{k} optionally further comprises one or more of —O—, —C(O)—, —S—, —S(O)—, or —S(O)₂—, wherein R^{7a} is substituted or unsubstituted C₁₋₃₀ alkyl, substituted or unsubstituted C₃₋₃₀ cycloalkyl, substituted or unsubstituted C₁₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₄₋₃₀ heteroaryl, substituted or unsubstituted C₅₋₃₀ heteroarylalkyl, or substituted or unsubstituted C₅₋₃₀ alkylheteroaryl;
n is an integer from 0 to 3;
L² is a divalent linking group;
R¹⁰ to R¹⁵ are each independently substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₄₋₂₀ heteroaryl;
optionally, any two or more of R¹⁰ to R¹² together form a ring; and
optionally, any two or more of R¹³ to R¹⁵ together form a ring.

5. The photoresist underlayer composition of claim 1, further comprising a compound of Formula (9), Formula (10), or a combination thereof: 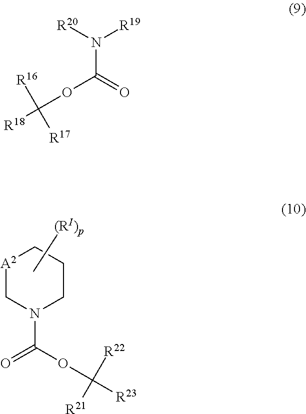
wherein, in Formulae (9) and (10),
R¹⁶ to R¹⁸ and R²¹ to R²³ are each independently substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₄₋₂₀ heteroaryl;
any two or more of R¹⁶ to R¹⁸ optionally together may form a ring, and any two or more of R²¹ to R²³ optionally together may form a ring;
R¹⁹ and R²⁰ are each independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
A² is a single bond or substituted or unsubstituted C₁₋₂ alkylene;
each R¹ is independently halogen, hydroxy, carboxylic acid, thiol, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
wherein R¹ optionally further comprises one or more of —O—, —C(O)—, —NR^{10a}—, —S—, —S(O)—, or —S(O)₂—, wherein R^{10a} is substituted or unsubstituted C₁₋₃₀ alkyl, substituted or unsubstituted C₃₋₃₀ cycloalkyl, substituted or unsubstituted C₁₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₄₋₃₀ heteroaryl, substituted or unsubstituted C₅₋₃₀ heteroarylalkyl, or substituted or unsubstituted C₅₋₃₀ alkylheteroaryl; and
p is an integer of 0 to 11.

6. The photoresist underlayer composition of claim 1, wherein the additive comprises one or more of the following compounds:

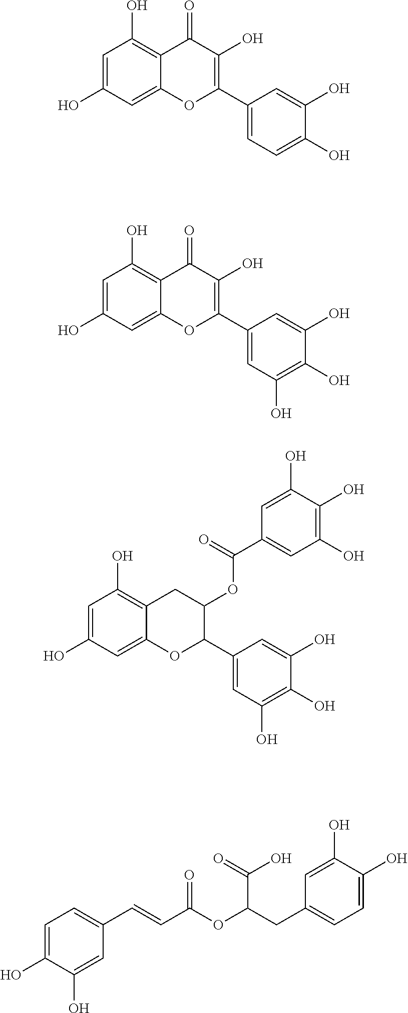

7. The photoresist underlayer composition of claim 1, wherein
the first material comprises a first polymer, wherein the first polymer comprises the two or more hydroxy groups; and
the second material is a second polymer, wherein the second polymer comprises the two or more glycidyl groups.

8. A coated substrate, comprising:
a layer of the photoresist underlayer composition of claim 1 disposed on a substrate; and
a photoresist layer disposed on the layer of the photoresist underlayer composition.

9. A method of forming a pattern, the method comprising:
applying a layer of the photoresist underlayer composition of claim 1, on a substrate to form a coated underlayer;
forming a photoresist layer over the coated underlayer;
patterning the photoresist layer; and
transferring a pattern from the patterned photoresist layer to the coated underlayer and to a layer below the coated underlayer.

10. The method of claim 9, further comprising:
forming a silicon-containing layer, an organic antireflective coating layer, or a combination thereof, over the coated underlayer prior to forming the photoresist layer; and
transferring the pattern to the silicon-containing layer, the organic antireflective coating layer, or the combination thereof, after developing an exposed photoresist layer and before the step transferring the pattern to the coated underlayer.

11. The coated substrate of claim 8, wherein the additive comprises a compound represented by Formula (5a): 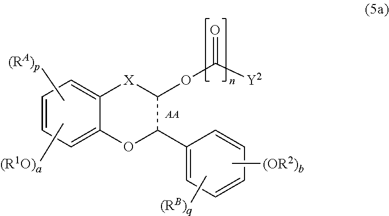
wherein, in Formulae (5a),
AA represents a single bond or a double bond;
X is a single bond, —C(O)—, unsubstituted C₁ alkylene, or hydroxy-substituted C₁ alkylene;
R¹ and R² are each independently hydrogen, substituted or unsubstituted C₁₋₃₀ alkyl, substituted or unsubstituted C₃₋₃₀ cycloalkyl, —C(O)OR^{5a}, or glycidyl;
each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{B} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{5a} is independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
a is an integer from 2 to 4;
b is an integer from 2 to 5;
n is 0 or 1;
p is an integer from 0 to 2;
q is an integer from 0 to 3; and
Y² is hydrogen, substituted or unsubstituted C₆₋₆₀ aryl, or substituted or unsubstituted C₁₋₆₀ heteroaryl.

12. The coated substrate of claim 8, wherein the additive comprises a compound represented by Formula (6a): 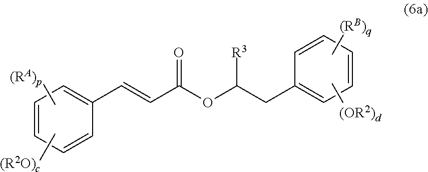
wherein, in Formulae (6a),
each R² is independently hydrogen, substituted or unsubstituted C₁₋₃₀ alkyl, substituted or unsubstituted C₃₋₃₀ cycloalkyl, —C(O)R^{5a}, or glycidyl;
each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{B} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{5a} is independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
R³ is hydrogen, substituted or unsubstituted C₁₋₃₀ alkyl, substituted or unsubstituted C₃₋₃₀ cycloalkyl, substituted or unsubstituted C₁₋₃₀ heterocycloalkyl, a carboxylic acid group or a derivative thereof, or —C(O)OR^{5b};
R^{5b} is substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
c is an integer from 2 to 5;
d is an integer from 2 to 5;
p is an integer from 0 to 2; and
q is an integer from 0 to 3.

13. The coated substrate of claim 8, further comprising a third polymer comprising a repeating unit derived from a monomer of Formulae (7), (8), or a combination thereof: 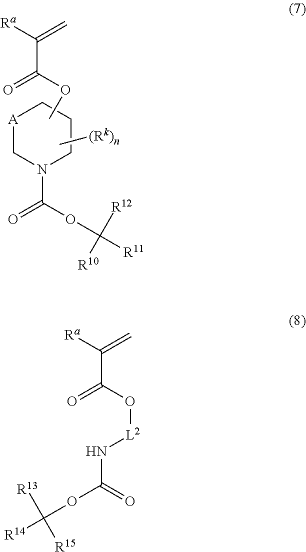
wherein, in Formulae (7) and (8),
each R^{a} is independently hydrogen, fluorine, a substituted or unsubstituted C₁₋₅ alkyl, or a substituted or unsubstituted C₁₋₅ fluoroalkyl;
A is a single bond or substituted or unsubstituted C₁₋₂ alkylene;
each R^{k} is independently halogen, hydroxyl, carboxyl, thiol, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl, wherein R^{k} optionally further comprises one or more of —O—, —C(O)—, —S—, —S(O)—, or —S(O)₂—, wherein R^{7a} is substituted or unsubstituted C₁₋₃₀ alkyl, substituted or unsubstituted C₃₋₃₀ cycloalkyl, substituted or unsubstituted C₁₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₄₋₃₀ heteroaryl, substituted or unsubstituted C₅₋₃₀ heteroarylalkyl, or substituted or unsubstituted C₅₋₃₀ alkylheteroaryl;
n is an integer from 0 to 3;
L² is a divalent linking group;
R¹⁰ to R¹⁵ are each independently substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₄₋₂₀ heteroaryl;
optionally, any two or more of R¹⁰ to R¹² together form a ring; and
optionally, any two or more of R¹³ to R¹⁵ together form a ring.

14. The coated substrate of claim 8, further comprising a compound of Formula (9), Formula (10), or a combination thereof: 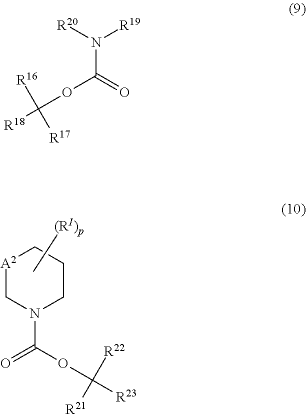
wherein, in Formulae (9) and (10),
R¹⁶ to R¹⁸ and R²¹ to R²³ are each independently substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₄₋₂₀ heteroaryl;
any two or more of R¹⁶ to R¹⁸ optionally together may form a ring, and any two or more of R²¹ to R²³ optionally together may form a ring;
R¹⁹ and R²⁰ are each independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
A² is a single bond or substituted or unsubstituted C₁₋₂ alkylene;
each R¹ is independently halogen, hydroxy, carboxylic acid, thiol, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
wherein R¹ optionally further comprises one or more of —O—, —C(O)—, —NR^{10a}—, —S—, —S(O)—, or —S(O)₂—, wherein R^{10a} is substituted or unsubstituted C₁₋₃₀ alkyl, substituted or unsubstituted C₃₋₃₀ cycloalkyl, substituted or unsubstituted C₁₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₄₋₃₀ heteroaryl, substituted or unsubstituted C₅₋₃₀ heteroarylalkyl, or substituted or unsubstituted C₅₋₃₀ alkylheteroaryl; and
p is an integer of 0 to 11.

15. The coated substrate of claim 8, wherein the additive comprises one or more of the following compounds:

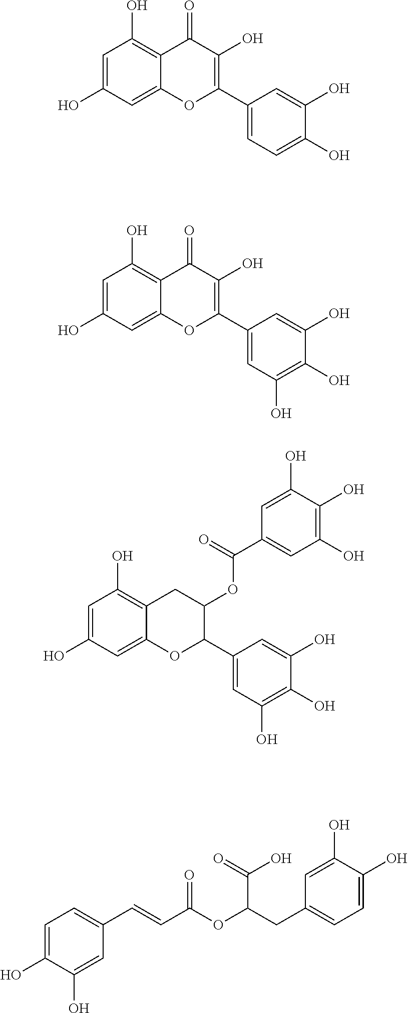

16. The coated substrate of claim 8, wherein
the first material comprises a first polymer, wherein the first polymer comprises the two or more hydroxy groups; and
the second material is a second polymer, wherein the second polymer comprises the two or more glycidyl groups.

17. The method of claim 9, wherein the additive comprises a compound represented by Formula (5a): 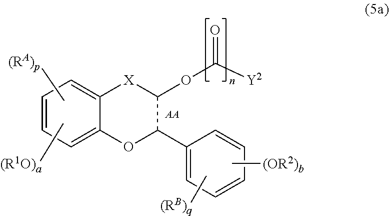
wherein, in Formulae (5a),
AA represents a single bond or a double bond;
X is a single bond, —C(O)—, unsubstituted C₁ alkylene, or hydroxy-substituted C₁ alkylene;
R¹ and R² are each independently hydrogen, substituted or unsubstituted C₁₋₃₀ alkyl, substituted or unsubstituted C₃₋₃₀ cycloalkyl, —C(O)OR^{5a}, or glycidyl;
each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{B} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{5a} is independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
a is an integer from 2 to 4;
b is an integer from 2 to 5;
n is 0 or 1;
p is an integer from 0 to 2;
q is an integer from 0 to 3; and
Y² is hydrogen, substituted or unsubstituted C₆₋₆₀ aryl, or substituted or unsubstituted C₁₋₆₀ heteroaryl.

18. The method of claim 9, wherein the additive comprises a compound represented by Formula (6a): 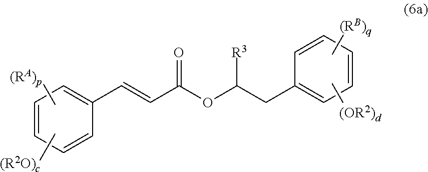
wherein, in Formulae (6a),
each R² is independently hydrogen, substituted or unsubstituted C₁₋₃₀ alkyl, substituted or unsubstituted C₃₋₃₀ cycloalkyl, —C(O)R^{5a}, or glycidyl;
each R^{A} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{B} is independently substituted or unsubstituted C₁₋₁₀ alkyl, substituted or unsubstituted C₁₋₁₀ heteroalkyl, substituted or unsubstituted C₃₋₁₀ cycloalkyl, substituted or unsubstituted C₂₋₁₀ heterocycloalkyl, substituted or unsubstituted C₆₋₁₂ aryl, or substituted or unsubstituted C₁₋₁₀ heteroaryl;
each R^{5a} is independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
R³ is hydrogen, substituted or unsubstituted C₁₋₃₀ alkyl, substituted or unsubstituted C₃₋₃₀ cycloalkyl, substituted or unsubstituted C₁₋₃₀ heterocycloalkyl, a carboxylic acid group or a derivative thereof, or —C(O)OR^{5b};
R^{5b} is substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
c is an integer from 2 to 5;
d is an integer from 2 to 5;
p is an integer from 0 to 2; and
q is an integer from 0 to 3.

19. The method of claim 9, further comprising a third polymer comprising a repeating unit derived from a monomer of Formulae (7), (8), or a combination thereof: 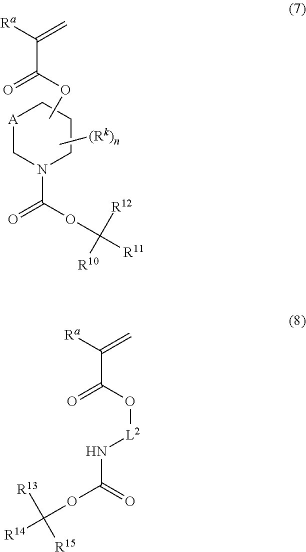
wherein, in Formulae (7) and (8),
each R^{a} is independently hydrogen, fluorine, a substituted or unsubstituted C₁₋₅ alkyl, or a substituted or unsubstituted C₁₋₅ fluoroalkyl;
A is a single bond or substituted or unsubstituted C₁₋₂ alkylene;
each R^{k} is independently halogen, hydroxyl, carboxyl, thiol, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl, wherein R^{k} optionally further comprises one or more of —O—, —C(O)—, —S—, —S(O)—, or —S(O)2—, wherein R^{7a} is substituted or unsubstituted C₁₋₃₀ alkyl, substituted or unsubstituted C₃₋₃₀ cycloalkyl, substituted or unsubstituted C₁₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₄₋₃₀ heteroaryl, substituted or unsubstituted C₅₋₃₀ heteroarylalkyl, or substituted or unsubstituted C₅₋₃₀ alkylheteroaryl;
n is an integer from 0 to 3;
L² is a divalent linking group;
R¹⁰ to R¹⁵ are each independently substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₄₋₂₀ heteroaryl;
optionally, any two or more of R¹⁰ to R¹² together form a ring; and
optionally, any two or more of R¹³ to R¹⁵ together form a ring.

20. The method of claim 9, further comprising a compound of Formula (9), Formula (10), or a combination thereof: 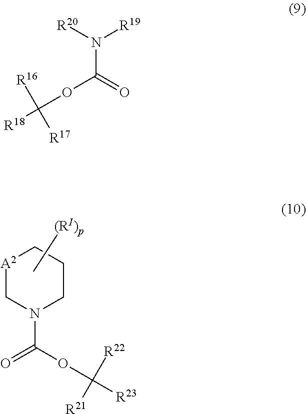
wherein, in Formulae (9) and (10),
R¹⁶ to R¹⁸ and R²¹ to R²³ are each independently substituted or unsubstituted C₁₋₂₀ alkyl, substituted or unsubstituted C₃₋₂₀ cycloalkyl, substituted or unsubstituted C₃₋₂₀ heterocycloalkyl, substituted or unsubstituted C₂₋₂₀ alkenyl, substituted or unsubstituted C₃₋₂₀ cycloalkenyl, substituted or unsubstituted C₃₋₂₀ heterocycloalkenyl, substituted or unsubstituted C₆₋₂₀ aryl, or substituted or unsubstituted C₄₋₂₀ heteroaryl;
any two or more of R¹⁶ to R¹⁸ optionally together may form a ring, and any two or more of R²¹ to R²³ optionally together may form a ring;
R¹⁹ and R²⁰ are each independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
A² is a single bond or substituted or unsubstituted C₁₋₂ alkylene;
each R¹ is independently halogen, hydroxy, carboxylic acid, thiol, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₁₋₃₀ heteroaryl, substituted or unsubstituted C₂₋₃₀ heteroarylalkyl, or substituted or unsubstituted C₂₋₃₀ alkylheteroaryl;
wherein R¹ optionally further comprises one or more of —O—, —C(O)—, —NR^{10a}—, —S—, —S(O)—, or —S(O)₂—, wherein R^{10a} is substituted or unsubstituted C₁₋₃₀ alkyl, substituted or unsubstituted C₃₋₃₀ cycloalkyl, substituted or unsubstituted C₁₋₂₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₄₋₃₀ heteroaryl, substituted or unsubstituted C₅₋₃₀ heteroarylalkyl, or substituted or unsubstituted C₅₋₃₀ alkylheteroaryl; and
p is an integer of 0 to 11.

21. The method of claim 9, wherein the additive comprises one or more of the following compounds:

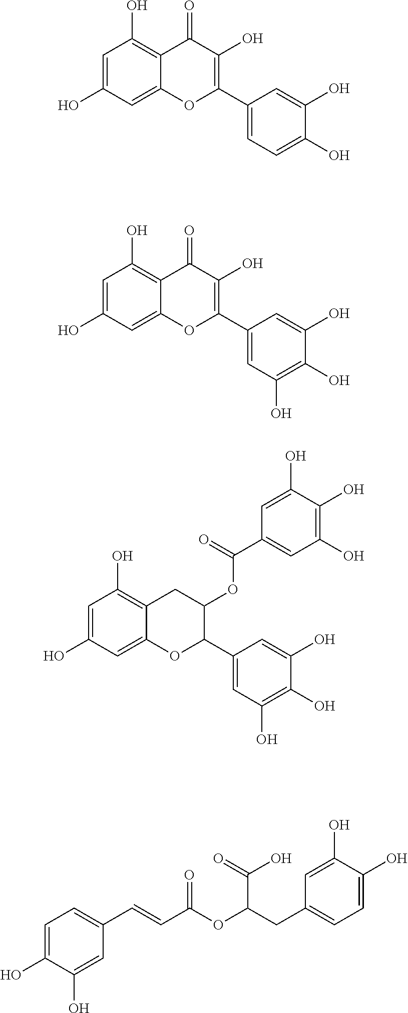

22. The method of claim 9, wherein
the first material comprises a first polymer, wherein the first polymer comprises the two or more hydroxy groups; and
the second material is a second polymer, wherein the second polymer comprises the two or more glycidyl groups.
